(19) United States
(12) Patent Application Publication
(10) Pub. No.: US 2022/0299872 A1
(43) Pub. Date: Sep. 22, 2022

(54) TRANSFER FILM AND METHOD FOR PRODUCING LAMINATE

(71) Applicant: FUJIFILM Corporation, Tokyo (JP)

(72) Inventors: Kentaro TOYOOKA, Fujinomiya-shi (JP); Yohei Aritoshi, Fujinomiya-shi (JP); Tatsuya Shimoyama, Fujinomiya-shi (JP)

(73) Assignee: FUJIFILM Corporation, Tokyo (JP)

(21) Appl. No.: 17/834,468

(22) Filed: Jun. 7, 2022

Related U.S. Application Data
(63) Continuation of application No. PCT/JP2020/044439, filed on Nov. 30, 2020.

(30) Foreign Application Priority Data
Dec. 27, 2019 (JP) 2019-238559

(51) Int. Cl. G03F 7/029; G03F 7/16; G03F 7/031

(52) U.S. Cl. CPC G03F 7/029; G03F 7/161; G03F 7/031; G06F 2203/04103; G06F 3/04164

(57) ABSTRACT

A transfer film has a temporary support and a photosensitive composition layer, in which the photosensitive composition layer includes a photopolymerization initiator, an alkali-soluble resin, and a polymerizable compound, the photopolymerization initiator includes a first photopolymerization initiator and a second photopolymerization initiator, a molar absorption coefficient ε1 of the first photopolymerization initiator at a wavelength of 365 nm is 500 L/mol·cm or more, and a ratio of a molar absorption coefficient ε2 of the second photopolymerization initiator at a wavelength of 365 nm to a molar absorption coefficient ε3 of the second photopolymerization initiator at a wavelength of 313 nm is 0.200 or less.

### CROSS-REFERENCE TO RELATED APPLICATIONS

This application is a Continuation of PCT International Application No. PCT/JP20201044439 filed on Nov. 30, 2020, which claims priority under 35 U.S.C § 119(a) to Japanese Patent Application No. 2019-238559 filed on Dec. 27, 2019. Each of the above application(s) is hereby expressly incorporated by reference, in its entirety, into the present application.

### BACKGROUND OF THE INVENTION

### 1. Field of the Invention

The present invention relates to a transfer film and a method for producing a laminate.

### 2. Description of the Related Art

From the viewpoint that the number of steps for obtaining a pattern having a predetermined shape is small, a method in which a photosensitive composition layer provided on any of substrates using a transfer film is exposed through a mask including a desired pattern, followed by development, has been widely used.

For example, a transfer film having a photosensitive composition layer is sometimes used in order to form a protective layer for protecting a sensor electrode and a lead wire in a touch panel. More specifically, a film (transfer film) comprising a photosensitive resin layer (photosensitive composition layer) including an alkali-soluble binder polymer, a photopolymerizable compound, and a photopolymerization initiator is disclosed in JP2019-175226A.

### SUMMARY OF THE INVENTION

On the other hand, in recent years, there has been a demand for further improvement in the shape of a pattern formed from a photosensitive composition layer. Specifically, it has been required that an edge portion should be linear in a case where a pattern on a substrate is visually recognized from the normal direction of the substrate without causing unevenness at the edge portion of the formed pattern. Hereinafter, in the present specification, a case where an edge portion of a pattern has no unevenness and is linear as described above is expressed as follows: the edge shape is excellent.

In addition, a pattern formed from a photosensitive composition layer is also required to have excellent scratch resistance.

The present inventors have performed formation of a pattern, using the transfer film having a photosensitive composition layer described in JP2019-175226A, and have thus found that the edge shape and the scratch resistance of a pattern thus formed could not be satisfied at the same time, and needed to be further improved.

Therefore, an object of the present invention is to provide a transfer film having a photosensitive composition layer, which is capable of forming a pattern having excellent scratch resistance and also having an excellent edge shape.

In addition, another object of the present invention is to provide a method for producing a laminate, using the transfer film.

The present inventors have conducted intensive studies to accomplish the objects, and as a result, they have found that the objects can be accomplished by the following configurations.

(1) A transfer film comprising:
a temporary support; and
a photosensitive composition layer,
in which the photosensitive composition layer includes a photopolymerization initiator, an alkali-soluble resin, and a polymerizable compound,
the photopolymerization initiator includes a first photopolymerization initiator and a second photopolymerization initiator,
a molar absorption coefficient ε1 of the first photopolymerization initiator at a wavelength of 365 nm is 500 L/mol·cm or more, and
a ratio of a molar absorption coefficient ε2 of the second photopolymerization initiator at a wavelength of 365 nm to a molar absorption coefficient ε3 of the second photopolymerization initiator at a wavelength of 313 nm is 0.200 or less.

(2) The transfer film as described in (1),
in which the ratio of the molar absorption coefficient ε2 of the second photopolymerization initiator at a wavelength of 365 nm to the molar absorption coefficient 3 of the second photopolymerization initiator at a wavelength of 313 nm is 0.100 or less.

(3) The transfer film as described in (1) or (2),
in which a maximum absorption wavelength of the second photopolymerization initiator is 320 nm or less.

(4) The transfer film as described in any one of (1) to (3)
in which a maximum absorption wavelength of the second photopolymerization initiator is 300 nm or less.

(5) The transfer film as described in any one of (1) to (4),
in which the second photopolymerization initiator includes at least one selected from the group consisting of an aminobenzoate-based photopolymerization initiator, an alkylphenone-based photopolymerization initiator, and an acylphosphine oxide-based photopolymerization initiator.

(6) The transfer film as described in any one of (1) to (5),
in which the second photopolymerization initiator includes an aminobenzoate-based photopolymerization initiator.

(7) The transfer film as described in any one of (1) to (6),
in which the first photopolymerization initiator includes at least one selected from the group consisting of an oxime ester-based photopolymerization initiator and an alkylphenone-based photopolymerization initiator.

(8) The transfer film as described in any one of (1) to (7),
in which a ratio of the molar absorption coefficient ε2 of the second photopolymerization initiator at a wavelength of 365 nm to the molar absorption coefficient εI of the first photopolymerization initiator at a wavelength of 365 nm is 0.50 or less.

(9) The transfer film as described in any one of (1) to (8),
in which the photosensitive composition layer is used for forming an electrode protective film.

(10) The transfer film as described in any one of (1) to (9), further comprising a refractive index-adjusting layer,
in which the refractive index-adjusting layer is arranged in contact with the photosensitive composition layer, and
a refractive index of the refractive index-adjusting layer is 1.60 or more.

(11) The transfer film as described in any one of (1) to (10),
in which the second photopolymerization initiator includes an aminobenzoate-based photopolymerization initiator, and
a maximum absorption wavelength of the second photopolymerization initiator is 300 nm or less.

(12) A method for producing a laminate, comprising:
affixing the transfer film as described in any one of (1) to (11) to a substrate having a conductive layer, with a photosensitive composition layer side of the transfer film thus facing the substrate, to obtain a substrate with a photosensitive composition layer;
exposing of pattern-exposing the photosensitive composition layer with light having a wavelength of 365 nm as a main wavelength;
developing the exposed photosensitive composition layer to form a pattern;
post-exposing of irradiating the pattern with light with which the second photopolymerization initiator is photosensitized; and
further peeling the temporary support from the substrate with a photosensitive composition layer, between the affixing and the exposing, or between the exposing and the developing.

(13) The method for producing a laminate as described in (12),
in which the substrate having a conductive layer is a substrate having a sensor electrode part for a touch panel and a lead wire part conducting with the sensor electrode for a touch panel.

According to the present invention, it is possible to provide a transfer film having a photosensitive composition, which is capable of forming a pattern having excellent scratch resistance and also having an excellent edge shape.

In addition, according to the present invention, it is possible to provide a method for producing a laminate, using the transfer film.

### DESCRIPTION OF THE PREFERRED EMBODIMENTS

Hereinafter, the details of the present invention will be described.

In the present specification, the numerical value range indicated by using “to” means a range including the numerical values before and after “to” as the lower limit value and the upper limit value, respectively.

In addition, regarding numerical ranges that are described stepwise in the present specification, an upper limit value or a lower limit value described in a numerical value may be replaced with an upper limit value or a lower limit value of another stepwise numerical range. In addition, in the range of numerical values disclosed in the present specification, an upper limit value and a lower limit value disclosed in a certain range of numerical values may be replaced with values shown in Examples.

Further, the term “step” in the present specification indicates not only an independent step but also a step which cannot be clearly distinguished from other steps as long as the intended purpose of the step is achieved.

In the present specification, a term “transparent” means that an average transmittance of visible light at a wavelength of 400 to 700 nm is 80% or more, and preferably 90% or more.

In addition, the average transmittance of visible light is a value measured using a spectrophotometer, and can be measured, for example, using a spectrophotometer U-3310 manufactured by Hitachi, Ltd.

In the present specification, a content ratio of the respective constitutional units of a polymer is a molar ratio unless otherwise specified.

In addition, the weight-average molecular weight (Mw) and the number-average molecular weight (Mn) in the present disclosure are molecular weights in terms of polystyrene used as a standard substance, which are detected by using tetrahydrofuran (THF), a differential refractometer, and a gel permeation chromatography (GPC) analyzer using TSKgel GMHxL, TSKgel G4000HxL, and TSKgel G2000HxL (all product names manufactured by Tosoh Corporation) as columns, unless otherwise specified.

In the present disclosure, unless otherwise specified, a molecular weight of a compound having a molecular weight distribution is the weight-average molecular weight (Mw).

In addition, in the present specification, the refractive index is a value measured with an ellipsometer at a wavelength of 550 nm unless otherwise specified.

In the present specification, “(meth)acryl” is a concept that encompasses both acryl and methacryl, and “(meth)acryloxy group” is a concept that encompasses both an acryloxy group and a methacryloxy group.

As will be described later, one of characteristic points of the transfer film of an embodiment of the present invention is that the photosensitive composition layer includes a first photopolymerization initiator and a second photopolymerization initiator, which satisfy predetermined characteristics.

The present inventors have examined the problems of the related art, and have thus found that in the related art using only one kind of photopolymerization initiator, the edge shape is deteriorated in a case where an exposure amount is increased in order to improve the scratch resistance of a pattern formed, and the scratch resistance is deteriorated in a case where an exposure amount is decreased in order to improve the edge shape.

On the other hand, the present inventors have found that in the present invention, desired effects can be obtained by using two kinds of photopolymerization initiators, that is, a first photopolymerization initiator that easily absorbs light upon pattern exposure using light at a wavelength of 365 nm as the main wavelength and sufficiently causes a polymerization reaction of a polymerizable compound, and a second photopolymerization initiator that is difficult to be photosensitized during exposure, easily absorbs light during post-exposure, and sufficiently causes a polymerization reaction of the polymerizable compound.

The transfer film of the embodiment of the present invention has at least a temporary support and a photosensitive composition layer.

Hereinafter, each member constituting the transfer film will be described in detail.

<Temporary Support>

The transfer film has a temporary support. The temporary support is a member that supports the photosensitive composition layer which will be described later, and the like, and is finally removed by a peeling treatment.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxially stretching polyethylene terephthalate film), a cellulose triacetate film, a polystyrene film, a polyimide film, and a polycarbonate film.

Among these, as the temporary support, a biaxially stretching polyethylene terephthalate film is preferable.

In addition, it is preferable that the film used as the temporary support does not have deformation such as wrinkles or scratches.

From the viewpoint that pattern exposure through the temporary support can be performed, it is preferable that the temporary support has high transparency, and the transmittance at 365 nm is preferably 60% or more, and more preferably 70% or more.

From the viewpoint of the pattern forming properties during pattern exposure through the temporary support and the transparency of the temporary support, it is preferable that a haze of the temporary support is small. Specifically, the haze value of the temporary support is preferably 2% or less, more preferably 0.5% or less, and still more preferably 0.1% or less.

From the viewpoint of the pattern forming properties during pattern exposure through the temporary support and the transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

A thickness of the temporary support is not particularly limited, but is preferably 5 to 200 μm, more preferably 10 to 150 μm, and still more preferably 10 to 50 μm from the viewpoint of easiness of handling and versatility.

From the viewpoint of imparting handleability, a layer (lubricant layer) containing fine particles may be provided on the surface of the temporary support. The lubricant layer may be provided on one surface of the temporary support or on both surfaces thereof. A diameter of the particles included in the lubricant layer may be 0.05 to 0.8 μm. In addition, a film thickness of the lubricant layer may be 0.05 μm to 1.0 μm.

In order to improve the adhesiveness between the temporary support and the photosensitive composition layer described later, a side of the temporary support in contact with the photosensitive composition layer may be surface-modified by UV irradiation, corona discharge, plasma, or the like.

In a case where the surface is modified by UV irradiation, the exposure amount is preferably 10 mJ/cm² to 2,000 mJ/cm² and more preferably 50 mJ/cm² to 1,000 mJ/cm².

Examples of a light source for UV irradiation include a low pressure mercury lamp, a high pressure mercury lamp, a ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 to 450 nm. As long as the amount of light irradiated is within the range, the lamp output or the illuminance is not particularly limited.

Examples of the temporary support include a biaxially stretching polyethylene terephthalate film having a film thickness of 16 μm, a biaxially stretching polyethylene terephthalate film having a film thickness of 12 μm, and a biaxially stretching polyethylene terephthalate film having a film thickness of 9 μm.

Preferred aspects of the temporary support are described in, for example, paragraphs [0017] and [0018] of JP2014-085643A, paragraphs [0019] to [0026] of JP2016-027363A, paragraphs [0041] to [0057] of WO2012/081680A1, and paragraphs [0029] to [0040] of WO2018/179370A1, the contents of which are incorporated herein by reference.

<Photosensitive Composition Layer>

The transfer film has a photosensitive composition layer. A pattern can be formed on an object to be transferred by transferring the photosensitive composition layer onto the object to be transferred, followed by performing exposure and development.

The photosensitive composition layer includes a photopolymerization initiator, an alkali-soluble resin, and a polymerizable compound.

In a case where the photosensitive composition layer is irradiated with light, polymerization proceeds and the exposed portion is cured. That is, the photosensitive composition layer is a layer that is exposed to light and cured, and is a so-called negative tone photosensitive composition layer (curable photosensitive composition layer).

Hereinafter, the components included in the photosensitive composition layer will be described in detail.

[Photopolymerization Initiator]

The photosensitive composition layer includes a first photopolymerization initiator and a second photopolymerization initiator.

The photopolymerization initiator means an agent that initiates the polymerization of a polymerizable compound by receiving actinic rays such as ultraviolet rays and visible light.

In the present disclosure, the values of a molar absorption coefficient and a maximum absorption wavelength are calculated from an absorption spectrum obtained as follows.

Specifically, first, an acetonitrile solution of a photopolymerization initiator having a concentration of 0.001% by mass is prepared, an absorbance of a solution thus obtained is measured using a spectrophotometer U-3310 manufactured by Hitachi, Ltd. (measurement range of 200 to 500 nm), and a molar absorption coefficient and a maximum absorption wavelength are calculated from an absorption spectrum thus obtained. [0026] (First Photopolymerization Initiator) The first photopolymerization initiator is not particularly limited as long as it is a photopolymerization initiator having a molar absorption coefficient ε1 at a wavelength of 365 nm of 500 L/mol·cm or more. Among those, the molar absorption coefficient ε1 is preferably 1,000 L/mol·cm or more, and more preferably 1,200 L/mol·cm or more from the viewpoint that at least one of an effect that the scratch resistance of a pattern thus formed is more excellent or an effect of the edge shape of a pattern thus formed is more excellent can be obtained (hereinafter simply expressed as follows: “that the effect of the present invention is more excellent”). The upper limit is not particularly limited, but it is often 30,000 L/mol·cm or less, and more often 20,000 L/mol·cm or less.

The maximum absorption wavelength of the first photopolymerization initiator is not particularly limited, but is preferably 300 nm or more, and more preferably 320 nm or more. The upper limit is not particularly limited, but is preferably 400 nm or less from the viewpoint that the effect of the present invention is more excellent. Incidentally, in a case where there are a plurality of maximum absorption wavelengths of the first photopolymerization initiator, a maximum absorption wavelength on the longest wavelength side is adopted.

Examples of the first photopolymerization initiator include a photopolymerization initiator including an oxime ester structure (hereinafter also referred to as an “oxime ester-based photopolymerization initiator”), a photopolymerization initiator including an α-aminoalkylphenone structure or an α-hydroxyalkylphenone structure (hereinafter also referred to as an “alkylphenone-based photopolymerization initiator”), a photopolymerization initiator including an acylphosphine oxide structure (hereinafter also referred to as an “acylphosphine oxide-based photopolymerization initiator”), a photopolymerization initiator including an aminobenzoic acid alkyl ester structure (hereinafter also referred to as an “aminobenzoate-based photopolymerization initiator”), and a photopolymerization initiator including an N-phenylglycine structure (hereinafter also referred to as an “N-phenylglycine-based photopolymerization initiator”).

Furthermore, examples of the aminobenzoate-based photopolymerization initiator include 2-ethylhexyl-4-dimethylaminobenzoate and ethyl-4-dimethylaminobenzoate.

The first photopolymerization initiator preferably includes at least one selected from the group consisting of an oxime ester-based photopolymerization initiator and an alkylphenone-based photopolymerization initiator.

A content of the first photopolymerization initiator is preferably 0.01% to 10% by mass, more preferably 0.1% to 5% by mass, and still more preferably 0.2% to 5% by mass with respect to the total mass of the photosensitive composition layer.

(Second Photopolymerization Initiator)

The second photopolymerization initiator is a compound different from the first photopolymerization initiator, and is not particularly limited as long as it is the photopolymerization initiator in which a ratio of the molar absorption coefficient ε2 of the second photopolymerization initiator at a wavelength of 365 nm to the molar absorption coefficient 3 of the second photopolymerization initiator at a wavelength of 313 nm (the molar absorption coefficient ε2 of the second photopolymerization initiator at a wavelength of 365 nm/the molar absorption coefficient ε3 of the second photopolymerization initiator at a wavelength of 313 nm) is 0.200 or less.

Among those, the ratio is preferably 0.100 or less, and more preferably 0.050 or less from the viewpoint that the effect of the present invention is more excellent. The lower limit is not particularly limited and may be, for example, 0.

The molar absorption coefficient ε2 of the second photopolymerization initiator at a wavelength of 365 nm is not particularly limited, but is preferably 1,500 L/mol·cm or less, more preferably 500 L/mol·cm or less, and still more preferably 200 L/mol·cm or less from the viewpoint that the effect of the present invention is more excellent. The lower limit is not particularly limited, but it is often 0 L/mol·cm or more, and more often 10 L/mol·cm or more.

The molar absorption coefficient ε3 of the second photopolymerization initiator at a wavelength of 313 nm is not particularly limited, but is preferably 2,000 L/mol·cm or more, more preferably 5,000 L/mol·cm or more, and still more preferably 10,000 L/mol·cm or more from the viewpoint that the effect of the present invention is more excellent. The upper limit is not particularly limited, but it is often 200,000 L/mol·cm or less, more often 30,000 L/mol·cm or less, and still more often 25,000 L/mol·cm or less.

The maximum absorption wavelength of the second photopolymerization initiator is not particularly limited, but is preferably 320 nm or less, and more preferably 300 nm or less from the viewpoint that the effect of the present invention is more excellent. The lower limit is not particularly limited, but is preferably 200 nm or more from the viewpoint that the effect of the present invention is more excellent. Furthermore, in a case where there are a plurality of maximum absorption wavelengths of the second photopolymerization initiator, a maximum absorption wavelength on the longest wavelength side is adopted.

Examples of the second photopolymerization initiator include the same compounds as the above-mentioned examples of the first photopolymerization initiator.

Among those, from the viewpoint that the effect of the present invention is more excellent, the second photopolymerization initiator preferably includes at least one selected from the group consisting of the aminobenzoate-based photopolymerization initiator, the alkylphenone-based photopolymerization initiator, and the acylphosphine oxide-based photopolymerization initiator, and more preferably includes the aminobenzoate-based photopolymerization initiator.

A content of the second photopolymerization initiator is preferably 0.01% to 10/o by mass, more preferably 0.1% to 5% by mass, and still more preferably 0.2% to 5% by mass with respect to the total mass of the photosensitive composition layer.

In addition, as the first photopolymerization initiator and the second photopolymerization initiator, for example, photopolymerization initiators disclosed in paragraphs [0031] to [0042] of JP2011-095716A and paragraphs [0064] to [0081] of JP2015-014783A may be used.

Examples of a commercially available product of the first photopolymerization initiator and the second photopolymerization initiator include 1-[4-(phenylthio)]phenyl-1,2-octanedione-2-(O-benzoyloxime) [product name: IRGACURE (registered trademark) OXE-01, manufactured by BASF], 1-[9-ethyl-6-(2-methylbenzoyl)-9H-carbazol-3-yl]ethanone-1-(0-acetyloxime) [product name: IRGACURE (registered trademark) OXE-02, manufactured by BASF], [8-[5-(2,4,6-trimethylphenyl)-11-(2-ethylhexyl)-11H-benzo[a]carbazoyl]][2-(2,2,3,3-tetrafluor opropoxy)phenyl]methanone-(O-acetyloxime) [product name: IRGACURE (registered trademark) OXE-03, manufactured by BASF], 1-[4-[4-(2-benzofuranylcarbonyl)phenyl]thio]phenyl-4-methyl-1-pentanone-1-(0-acetyloxime) [product name: IRGACURE (registered trademark) OXE-04, manufactured by BASF], 2-(dimethylamino)-2-[(4-methylphenyl)methyl]-1-[4-(4-morpholinyl)phenyl]-1-butanone [product name: IRGACURE (registered trademark) 379EG, manufactured by BASF], 2-methyl-1-(4-methylthiophenyl)-2-morpholinopropan-1-one [product name: IRGACURE (registered trademark) 907, manufactured by BASF], 2-hydroxy-1-{4-[4-(2-hydroxy-2-methyl-propionyl)benzyl]phenyl}-2-methylpropan-1-one [product name: IRGACURE (registered trademark) 127, manufactured by BASF], 2-benzyl-2-dimethylamino-1-(4-morpholinophenyl)-butanone-1 [product name: IRGACURE (registered trademark) 369, manufactured by BASF], 2-hydroxy-2-methyl-1-phenyl-propan-1-one [product name: IRGACURE (registered trademark) 1173, manufactured by BASF], 1-hydroxy cyclohexyl phenyl ketone [product name: IRGACURE (registered trademark) 184, manufactured by BASF], 2,2-dimethoxy-1,2-diphenylethan-1-one (product name: IRGACURE (registered trademark) 651, manufactured by BASF], an oxime ester-based compound [product name: Lunar (registered trademark) 6, manufactured by DKSH Management Ltd.], ethyl 4-(dimethylamino)benzoate [product name: DAROCUR EDB, manufactured by BASF], 2-hydroxy-4′-(2-hydroxyethoxy)-2-methylpropiophenone [product name: IRGACURE (registered trademark) 2959, manufactured by BASF], and phenylbis(2,4,6-trimethylbenzoyl) phosphine oxide [product name: IRGACURE (registered trademark) 819, manufactured by BASF].

A ratio of the molar absorption coefficient 2 of the second photopolymerization initiator at a wavelength of 365 nm to the molar absorption coefficient ε1 of the first photopolymerization initiator at a wavelength of 365 nm is not particularly limited, but is preferably 0.500 or less, and more preferably 0.200 or less from the viewpoint that the effect of the present invention is more excellent. The lower limit is not particularly limited, but is 0.01 or more in many cases.

Moreover, from the viewpoint that the effect of the present invention is more excellent, it is preferable that an absorbance of the second photopolymerization initiator at a wavelength of 313 nm is larger than an absorbance of the first photopolymerization initiator at a wavelength of 313 nm.

The photosensitive composition layer may include at least two kinds of photopolymerization initiators, that is, a first photopolymerization initiator and a second photopolymerization initiator, and may also include three or more kinds of photopolymerization initiators.

A total content of the photopolymerization initiators is preferably 0.10% by mass or more, and more preferably 0.50% by mass or more with respect to the total mass of the photosensitive composition layer. In addition, the upper limit of the content of the photopolymerization initiator is preferably 10% by mass or less, and more preferably 5.0% by mass or less with respect to the total mass of the photosensitive composition layer.

The total content of the photopolymerization initiators means a total content of all the photopolymerization initiators including the first photopolymerization initiator and the second photopolymerization initiator.

A content of the second photopolymerization initiator is preferably 1.2 times or more, and more preferably 1.5 times or more the content of the first photopolymerization initiator.

The upper limit is not particularly limited, but is often 5 times or less.

[Alkali-Soluble Resin]

The photosensitive composition layer includes an alkali-soluble resin.

By incorporating the alkali-soluble resin into the photosensitive composition layer, the solubility of the photosensitive composition layer (non-exposed portion) in a developer is improved.

As the alkali-soluble resin, an alkali-soluble acrylic resin is preferable.

Hereinafter, the alkali-soluble acrylic resin will be described in detail.

In the present disclosure, “alkali-soluble” means that the dissolution rate obtained by the following method is 0.01 μm/sec or more.

A propylene glycol monomethyl ether acetate solution having a concentration of a target compound (for example, a resin) of 25% by mass is applied to a glass substrate, and then heated in an oven at 100° C. for 3 minutes to form a coating film (thickness of 2.0 μm) of the target compound. The coating film is immersed in a 1% by mass aqueous solution of sodium carbonate (liquid temperature of 30° C.), thereby obtaining the dissolution rate (μm/sec) of the coating film.

In a case where the target compound is not dissolved in propylene glycol monomethyl ether acetate, the target compound is dissolved in an organic solvent (for example, tetrahydrofuran, toluene, and ethanol) having a boiling point of lower than 200° C., other than propylene glycol monomethyl ether acetate.

The alkali-soluble acrylic resin is not limited as long as it is the alkali-soluble acrylic resin described above. Here, “acrylic resin” means a resin containing at least one of a constitutional unit derived from a (meth)acrylic acid or a constitutional unit derived from a (meth)acrylic acid ester.

A total ratio of the constitutional unit derived from a (meth)acrylic acid and the constitutional unit derived from a (meth)acrylic acid ester in the alkali-soluble acrylic resin is preferably 30% by mole or more, and more preferably 50% by mole or more.

In the present disclosure, in a case where the content of “constitutional unit” is specified by mole fraction (molar proportion), the “constitutional unit” is synonymous with “monomer unit” unless otherwise specified. In addition, in the present disclosure, in a case where a resin or polymer has two or more specific constitutional units, the content of the specific constitutional units indicates the total content of the two or more specific constitutional units unless otherwise specified.

From the viewpoint of developability, the alkali-soluble acrylic resin preferably has a carboxyl group. Examples of a method for introducing the carboxyl group into the alkali-soluble acrylic resin include a method of synthesizing an alkali-soluble acrylic resin using a monomer having a carboxyl group. By the method, the monomer having a carboxyl group is introduced into the alkali-soluble acrylic resin as a constitutional unit having a carboxyl group. Examples of the monomer having a carboxyl group include acrylic acid and methacrylic acid.

The alkali-soluble acrylic resin may have one carboxyl group or two or more carboxyl groups. In addition, the alkali-soluble acrylic resin may have only one kind of constitutional unit having a carboxyl group, or may have two or more kinds of constitutional units.

A content of the constitutional unit having a carboxyl group is preferably 5% to 50% by mole, more preferably 5% to 40% by mole, and still more preferably 10% to 30% by mole with respect to the total amount of the alkali-soluble acrylic resin.

The content of the constitutional unit having a carboxyl group is preferably 3% to 40% by mass, more preferably 3% to 30% by mass, and still more preferably 5% to 20% by mass in terms of a mass ratio with respect to the total amount of the alkali-soluble acrylic resin.

Examples of the (meth)acrylic compound for forming an acrylic resin include a (meth)acrylic acid, a (meth)acrylic acid ester, a (meth)acrylamide, and a (meth)acrylonitrile.

Examples of the (meth)acrylic acid ester include an alkyl (meth)acrylate ester, a tetrahydrofurfuryl (meth)acrylate ester, a dimethylaminoethyl (meth)acrylate ester, a diethylaminoethyl (meth)acrylate ester, a (meth)acrylic acid ester, a glycidyl acrylate ester, a benzyl (meth)acrylate ester, a 2,2,2-trifluoroethyl (meth)acrylate, and 2,2,3,3-tetrafluoropropyl (meth)acrylate, and the alkyl (meth)acrylate ester is preferable.

Examples of the (meth)acrylamide include acrylamides such as diacetone acrylamide.

The alkyl group of the alkyl (meth)acrylate ester may be linear or branched.

Specific examples of the alkyl (meth)acrylate ester include alkyl (meth)acrylate esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid ester, an alkyl (meth)acrylate ester having an alkyl group having 1 to 4 carbon atoms is preferable, and methyl (meth)acrylate or ethyl (meth)acrylate is more preferable.

The acrylic resin may have a constitutional unit other than the constitutional unit derived from the (meth)acrylic compound.

From the viewpoint of moisture permeability and hardness after curing, the alkali-soluble acrylic resin preferably has a constitutional unit having an aromatic ring. The constitutional unit having an aromatic ring is preferably a constitutional unit derived from a styrene compound.

Examples of a monomer that forms the constitutional unit having an aromatic ring include a monomer forming a constitutional unit derived from a styrene compound and benzyl (meth)acrylate.

Examples of the monomer forming a constitutional unit derived from a styrene compound include styrene, p-methylstyrene, α-methylstyrene, α,p-dimethylstyrene, p-ethylstyrene, p-t-butylstyrene, t-butoxystyrene, and 1,1-diphenylethylene, and styrene or α-methylstyrene is preferable and styrene is more preferable.

The alkali-soluble acrylic resin may have only one kind of constitutional unit having an aromatic ring, or two or more kinds of the constitutional units.

In a case where the alkali-soluble acrylic resin has a constitutional unit having an aromatic ring, the content of the constitutional unit having an aromatic ring is preferably 5% to 90% by mole, more preferably 10% to 80% by mole, and still more preferably 15% to 70% by mole with respect to the total amount of the alkali-soluble acrylic resin.

From the viewpoint of tackiness and hardness after curing, the alkali-soluble acrylic resin preferably includes a constitutional unit having an aliphatic cyclic skeleton. Examples of the aliphatic cyclic skeleton include a monocycle and a polycycle.

Examples of an aliphatic ring in the aliphatic cyclic skeleton include a dicyclopentane ring, a cyclohexane ring, an isophorone ring, and a tricyclodecane ring. Among those, a tricyclodecane ring is preferable as the aliphatic ring in the aliphatic cyclic skeleton.

Examples of a monomer that forms the constitutional unit having an aliphatic cyclic skeleton include dicyclopentanyl (meth)acrylate, cyclohexyl (meth)acrylate, and isobornyl (meth)acrylate.

The alkali-soluble acrylic resin may have only one kind of constitutional unit having an aliphatic cyclic skeleton, or two or more kinds of the constitutional units.

In a case where the alkali-soluble acrylic resin has a constitutional unit having an aliphatic cyclic skeleton, the content of the constitutional unit having an aliphatic cyclic skeleton is preferably 5% to 90% by mole, more preferably 10% to 80% by mole, and still more preferably 10/o to 60% by mole with respect to the total amount of the alkali-soluble acrylic resin.

From the viewpoint of tackiness and hardness after curing, the alkali-soluble acrylic resin preferably has a reactive group.

As the reactive group, a radically polymerizable group is preferable, and an ethylenically unsaturated group is more preferable. In addition, in a case where the alkali-soluble acrylic resin has an ethylenically unsaturated group, the alkali-soluble acrylic resin preferably has a constitutional unit having an ethylenically unsaturated group in a side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryloyl group or a (meth)acryloxy group, and more preferably a (meth)acryloxy group.

The alkali-soluble acrylic resin may have only one kind of constitutional unit having an ethylenically unsaturated group, or two or more kinds of the constitutional units.

In a case where the alkali-soluble acrylic resin has a constitutional unit having an ethylenically unsaturated group, the content of the constitutional unit having an ethylenically unsaturated group is preferably 5% to 70% by mole, more preferably 10% to 50% by mole, and still more preferably 15% to 40% by mole with respect to the total amount of the alkali-soluble acrylic resin.

Examples of the constitutional unit having a reactive group include those shown below, but the constitutional unit having a reactive group is not limited thereto.

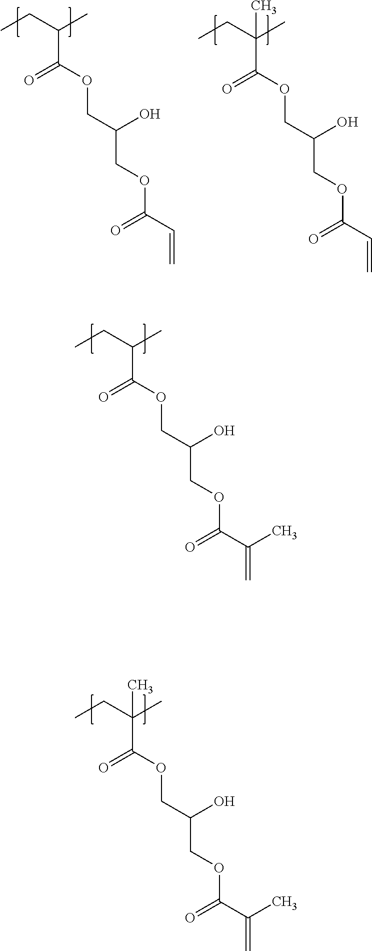

Examples of a method for introducing the reactive group into the alkali-soluble acrylic resin include a method of reacting an epoxy compound, a blocked isocyanate compound, an isocyanate compound, a vinyl sulfone compound, an aldehyde compound, a methylol compound, a carboxylic acid anhydride, or the like with a hydroxyl group, a carboxyl group, a primary amino group, a secondary amino group, an acetoacetyl group, a sulfonic acid, and the like.

Preferred examples of the method for introducing the reactive group into the alkali-soluble acrylic resin include a method in which an alkali-soluble acrylic resin having a carboxyl group is synthesized by a polymerization reaction, and then a glycidyl (meth)acrylate is reacted with a part of the carboxyl group of the alkali-soluble acrylic resin by a polymer reaction, thereby introducing a (meth)acryloxy group into the alkali-soluble acrylic resin. By the method, an alkali-soluble acrylic resin having a (meth)acryloxy group in the side chain can be obtained.

The polymerization reaction is preferably carried out under a temperature condition of 70° C. to 100° C., and more preferably carried out under a temperature condition of 80° C. to 90° C. As a polymerization initiator used in the polymerization reaction, an azo-based initiator is preferable, and for example, V-601 (product name) or V-65 (product name) manufactured by FUJIFILM Wako Pure Chemical Corporation is more preferable. In addition, the polymer reaction is preferably carried out under a temperature condition of 80° C. to 110° C. In the polymer reaction, it is preferable to use a catalyst such as an ammonium salt.

The weight-average molecular weight (Mw) of the alkali-soluble acrylic resin is preferably 10,000 or more, more preferably 10,000 to 100,000, still more preferably 15,000 to 70,000, and most preferably 15,000 to 30,000.

From the viewpoint of developability, an acid value of the alkali-soluble acrylic resin is preferably 50 mgKOH/g or more, more preferably 60 mgKOH/g or more, still more preferably 70 mgKOH/g or more, and particularly preferably 80 mgKOH/g or more. In the present disclosure, the acid value of the alkali-soluble acrylic resin is a value measured according to the method described in JIS K0070: 1992.

From the viewpoint of suppressing dissolution in a developer, the acid value of the alkali-soluble acrylic resin is preferably 200 mgKOH/g or less, and more preferably 150 mgKOH/g or less.

Specific examples of the alkali-soluble acrylic resin are shown below. Furthermore, a content ratio (molar ratio) of each constitutional unit in the following alkali-soluble acrylic resins can be appropriately set according to the purpose.

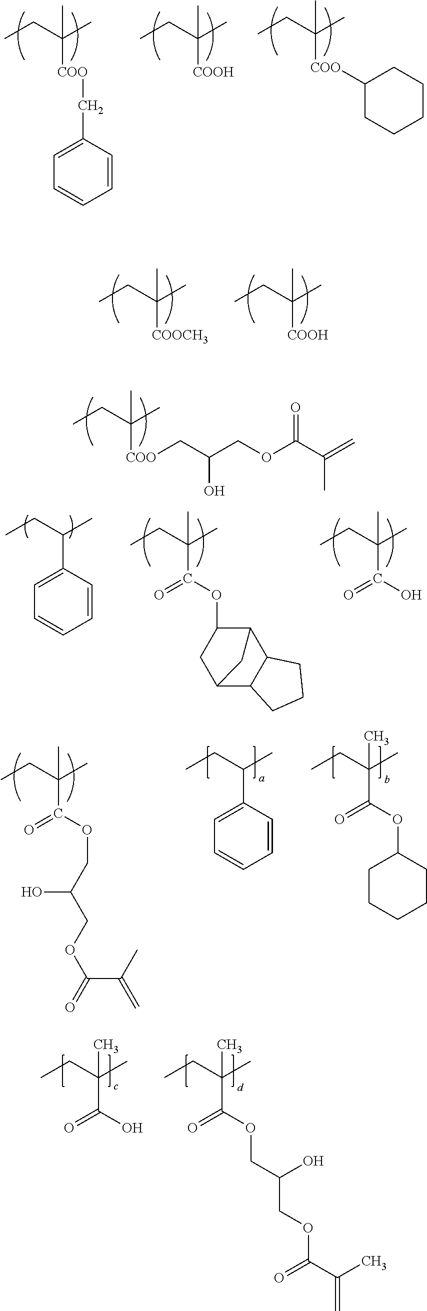

In the chemical formulae, a: 20% by weight to 60% by weight, b: 10% by weight to 50% by weight, c: 5.0% by weight to 25% by weight, and d: 10% by weight to 50% by weight are preferable.

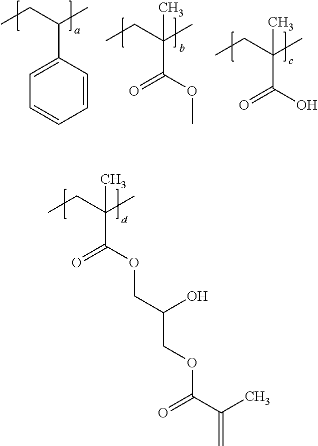

In the chemical formulae, a: 30% by weight to 65% by weight, b: 1.0% by weight to 20% by weight, c: 5.0% by weight to 25% by weight, and d: 10% by weight to 50% by weight are preferable.

The photosensitive composition layer may include only one kind of alkali-soluble resin, or may include two or more kinds of alkali-soluble resins.

From the viewpoint of patterning properties and reliability, the content of residual monomer of each constitutional unit of the alkali-soluble resin is preferably 2,000 ppm by mass or less, more preferably 1,000 ppm by mass or less, and still more preferably 500 ppm by mass or less with respect to the total mass of the alkali-soluble resin. The lower limit is not particularly limited, but is preferably 1 ppm by mass or more, and more preferably 10 ppm by mass or more.

From the viewpoint of patterning properties and reliability, the residual monomer of each constitutional unit in the alkali-soluble resin is preferably 1,000 ppm by mass or less, more preferably 200 ppm by mass or less, and still more preferably 100 ppm by mass or less with respect to the total mass of the photosensitive composition layer. The lower limit is not particularly limited, but is preferably 0.1 ppm by mass or more, and more preferably 1 ppm by mass or more.

From the viewpoint of developability, a content of the alkali-soluble resin is preferably 10% to 90% by mass, more preferably 20% to 80% by mass, and still more preferably 25% to 70% by mass with respect to the total mass of the photosensitive composition layer.

[Polymerizable Compound]

The photosensitive composition layer includes a polymerizable compound.

The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter also simply referred to as an “ethylenically unsaturated compound”).

As the ethylenically unsaturated group, a (meth)acryloxy group is preferable.

The ethylenically unsaturated compound preferably includes a bi- or higher functional ethylenically unsaturated compound. Here, the “bi- or higher functional ethylenically unsaturated compound” means a compound having two or more ethylenically unsaturated groups in one molecule.

As the ethylenically unsaturated compound, a (meth)acrylate compound is preferable.

From the viewpoint of film hardness after curing, for example, the ethylenically unsaturated compound preferably includes a bifunctional ethylenically unsaturated compound (preferably a bifunctional (meth)acrylate compound) and a tri- or higher functional ethylenically unsaturated compound (preferably a tri- or higher functional (meth)acrylate compound).

Examples of the bifunctional ethylenically unsaturated compound include tricyclodecane dimethanol di(meth)acrylate, tricyclodecane dimethanol di(meth)acrylate, 1,9-nonanediol di(meth)acrylate, 1,10-decanediol di(meth)acrylate, and 1,6-hexanediol di(meth)acrylate.

Examples of a commercially available product of the bifunctional ethylenically unsaturated compound include tricyclodecane dimethanol diacrylate [product name: NK ESTER A-DCP, Shin-Nakamura Chemical Co., Ltd.], tricyclodecane dimethanol dimethacrylate [product name: NK ESTER DCP, Shin-Nakamura Chemical Co., Ltd.], 1,9-nonanediol diacrylate [product name: NK ESTER A-NOD-N, Shin-Nakamura Chemical Co., Ltd.], 1,10-decanediol diacrylate [product name: NK ESTER A-DOD-N, Shin-Nakamura Chemical Co., Ltd.], and 1,6-hexanediol diacrylate [product name: NK ESTER A-HD-N, Shin-Nakamura Chemical Co., Ltd.].

Examples of the tri- or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, isocyanuric acid (meth)acrylate, and glycerin tri(meth)acrylate.

Here, the “(tri/tetra/penta/hexa)(meth)acrylate” is a concept including tri(meth)acrylate, tetra(meth)acrylate, penta(meth)acrylate, and hexa(meth)acrylate. In addition, the “(tri/tetra)(meth)acrylate” is a concept including tri(meth)acrylate and tetra(meth)acrylate.

The tri- or higher functional ethylenically unsaturated compound is not particularly limited in the upper limit of the number of functional groups, but the number of functional groups can be, for example, 20 or less, or can be 15 or less.

Examples of a commercially available product of the tri- or higher functional ethylenically unsaturated compound include dipentaerythritol hexaacrylate [product name: A-DPH, Shin-Nakamura Chemical Co., Ltd.].

The ethylenically unsaturated compound more preferably includes 1,9-nonanediol di(meth)acrylate or 1,10-decanediol di(meth)acrylate, and dipentaerythritol (tri/tetra/penta/hexa)(meth)acrylate.

Examples of the ethylenically unsaturated compound also include a caprolactone-modified compound of a (meth)acrylate compound [KAYARAD (registered trademark) DPCA-20 of Nippon Kayaku Co., Ltd., A-9300-1CL of Shin-Nakamura Chemical Co., Ltd., or the like], an alkylene oxide-modified compound of a (meth)acrylate compound [KAYARAD (registered trademark) RP-1040 of Nippon Kayaku Co., Ltd., ATM-35E or A-9300 of Shin-Nakamura Chemical Co., Ltd., EBECRYL (registered trademark) 135 of Daicel-Allnex Ltd., or the like], and ethoxylated glycerin triacrylate [NK ESTER A-GLY-9E of Shin-Nakamura Chemical Co., Ltd., or the like].

Examples of the ethylenically unsaturated compound also include a urethane (meth)acrylate compound. As the urethane (meth)acrylate compound, a tri- or higher functional urethane (meth)acrylate compound is preferable. Examples of the tri- or higher functional urethane (meth)acrylate compound include 8UX-015A [Taisei Fine Chemical Co., Ltd.], NK ESTER UA-32P [Shin-Nakamura Chemical Co., Ltd.], and NK ESTER UA-1100H [Shin-Nakamura Chemical Co., Ltd.].

In addition, the ethylenically unsaturated compound preferably includes an ethylenically unsaturated compound having an acid group, from a viewpoint of improving developability.

Examples of the acid group include a phosphoric acid group, a sulfonic acid group, and a carboxyl group. Among those, as the acid group, a carboxyl group is preferable.

Examples of the ethylenically unsaturated compound having an acid group include a tri- or tetrafunctional ethylenically unsaturated compound having an acid group [compound obtained by introducing a carboxyl group to pentaerythritol tri- and tetraacrylate (PETA) skeletons (acid value: 80 to 120 mgKOH/g)], and a penta- or hexafunctional ethylenically unsaturated compound having an acid group [compound obtained by introducing a carboxyl group to a dipentaerythritol penta- or hexaacrylate (DPHA) skeleton (acid value: 25 to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one compound selected from the group consisting of bi- or higher functional ethylenically unsaturated compound having a carboxyl group and a carboxylic acid anhydride thereof is preferable. In a case where the ethylenically unsaturated compound having an acid group is at least one compound selected from the group consisting of a bi- or higher functional ethylenically unsaturated compound having a carboxyl group and a carboxylic acid anhydride thereof, the developability and the film hardness are further enhanced.

Examples of the bi- or higher functional ethylenically unsaturated compound having a carboxyl group include ARONIX (registered trademark) TO-2349 [Toagosei Co., Ltd.], ARONIX (registered trademark) M-520 [Toagosei Co., Ltd.], and ARONIX (registered trademark) M-510 [Toagosei Co., Ltd.].

As the ethylenically unsaturated compound having an acid group, polymerizable compounds having an acid group, which are described in paragraphs [0025] to [0030] of JP2004-239942A, can be preferably used, and the contents described in this publication are incorporated herein by reference.

A molecular weight of the ethylenically unsaturated compound is preferably 200 to 3,000, more preferably 250 to 2,600, still more preferably 280 to 2,200, and particularly preferably 300 to 2,200.

A content of the ethylenically unsaturated compound having a molecular weight of 300 or less among the ethylenically unsaturated compounds is preferably 30% by mass or less, more preferably 25% by mass or less, and still more preferably 20% by mass or less with respect to the content of all the ethylenically unsaturated compounds included in the photosensitive composition layer.

The photosensitive composition layer may include only one kind of ethylenically unsaturated compound, or may include two or more kinds of ethylenically unsaturated compounds.

The content of the ethylenically unsaturated compound is preferably 1% to 70% by mass, more preferably 10% to 70% by mass, still more preferably 20% to 60% by mass, and particularly preferably 20% to 50% by mass, with respect to a total mass of the photosensitive composition layer.

In a case where the photosensitive composition layer includes a bi- or higher functional ethylenically unsaturated compound, the photosensitive composition layer may further include a monofunctional ethylenically unsaturated compound.

In a case where the photosensitive composition layer includes a bi- or higher functional ethylenically unsaturated compound, it is preferable that the bi- or higher functional ethylenically unsaturated compound is a main component of ethylenically unsaturated compounds included in the photosensitive composition layer.

In a case where the photosensitive composition layer includes a bi- or higher functional ethylenically unsaturated compound, a content of the bi- or higher functional ethylenically unsaturated compound is preferably 60/to 100% by mass, more preferably 80% to 100% by mass, and still more preferably 90% to 100% by mass with respect to the content of all the ethylenically unsaturated compounds included in the photosensitive composition layer.

In a case where the photosensitive composition layer includes the ethylenically unsaturated compound having an acid group (preferably di- or higher functional ethylenically unsaturated compound having a carboxyl group or a carboxylic acid anhydride thereof), the content of the ethylenically unsaturated compound having an acid group is preferably 1% to 50% by mass, more preferably 1% to 20% by mass, and still more preferably 1% to 10% by mass, with respect to the total mass of the photosensitive composition layer.

[Polymer including Constitutional Unit having Carboxylic Acid Anhydride Structure]

The photosensitive composition layer may further include, as the binder, a polymer (hereinafter also referred to as a “polymer B”) including a constitutional unit having a carboxylic acid anhydride structure. By incorporating the polymer B into the photosensitive composition layer, the developability and the hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5- to 7-membered ring, more preferably a 5-membered ring or a 6-membered ring, and still more preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

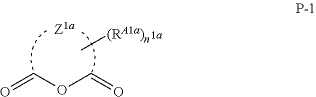

In Formula P-1, R^{A1a} represents a substituent, n^{1a} pieces of R^{A1a}s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s existing may be the same or different. In addition, the plurality of R^{A1a}'S existing may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic anhydride or itaconic anhydride is particularly preferable, and a constitutional unit derived from maleic acid anhydride is the most preferable.

The polymer B may have only one kind of constitutional unit having a carboxylic acid anhydride structure, or two or more kinds thereof.

A content of the constitutional unit having a carboxylic acid anhydride structure is preferably 0% to 60% by mole, more preferably 5% to 40% by mole, and still more preferably 10% to 35% by mole with respect to the total amount of the polymer B.

The photosensitive composition layer may include only one kind of polymer B, or may include two or more kinds of polymers B.

In a case where the photosensitive composition layer includes the polymer B, from the viewpoints of the developability and the strength after curing, a content of the polymer B is preferably 0.1% to 30/o by mass, more preferably 0.2% to 20% by mass, still more preferably 0.5% to 20% by mass, and particularly preferably 1% to 20% by mass with respect to the total mass of the photosensitive composition layer

[Heterocyclic Compound]

It is preferable that the photosensitive composition layer includes a heterocyclic compound.

A heterocyclic ring contained in the heterocyclic compound may be either a monocyclic or polycyclic heterocyclic ring.

Examples of a heteroatom contained in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

Among those, as the heterocyclic compound, at least one compound selected from the group consisting of the triazole compound, the benzotriazole compound, the tetrazole compound, the thiadiazole compound, the triazine compound, the rhodanine compound, the thiazole compound, the benzimidazole compounds, and the benzoxazole compound is preferable, and at least one compound selected from the group consisting of the triazole compound, the benzotriazole compound, the tetrazole compound, the thiadiazole compound, the thiazole compound, the benzothiazole compound, the benzimidazole compound, and the benzoxazole compound is more preferable.

Preferred specific examples of the heterocyclic compound are shown below. The following compounds can be exemplified as a triazole compound and a benzotriazole compound.

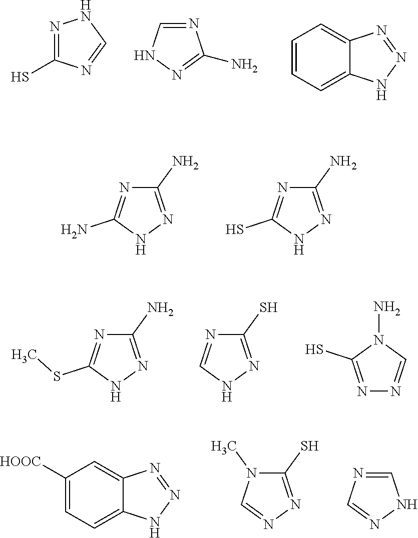

Examples of the tetrazole compound include the following compounds.

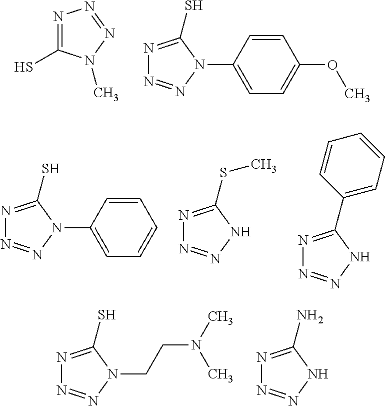

Examples of the triazine compound include the following compounds.

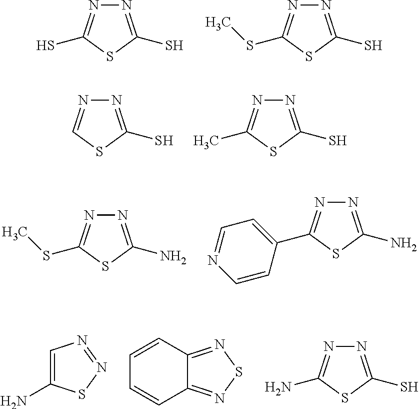

Examples of the triazine compound include the following compounds.

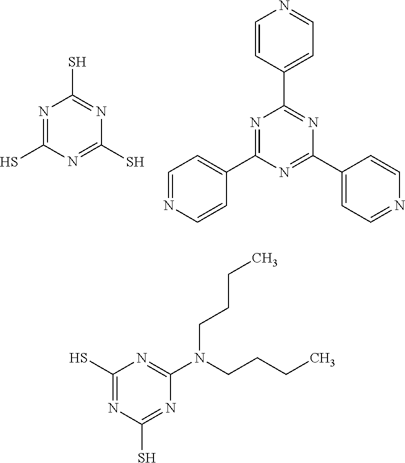

The following compounds can be exemplified as a rhodanine compound.

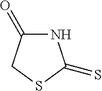

Examples of the thiazole compound include the following compounds.

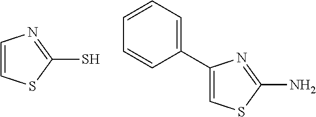

Examples of the benzothiazole compound include the following compounds.

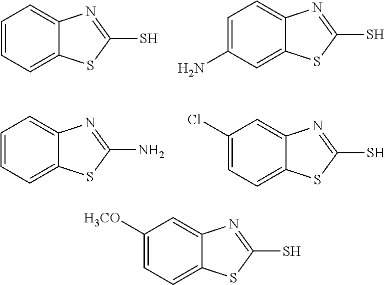

Examples of the benzimidazole compound include the following compounds.

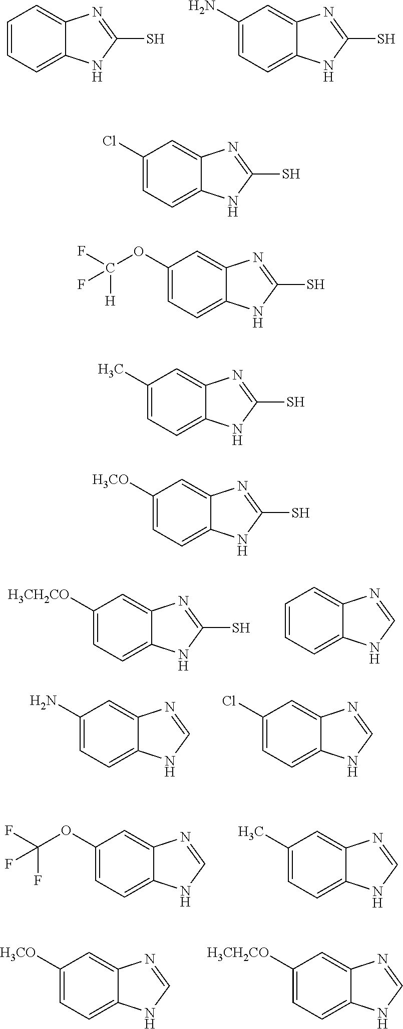

Examples of the benzoxazole compound include the following compounds.

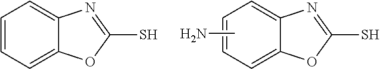

The photosensitive composition layer may include only one kind of heterocyclic compound, or may include two or more kinds of heterocyclic compounds.

In a case where the photosensitive composition layer includes the heterocyclic compound, a content of the heterocyclic compound is preferably 0.01% to 20% by mass, and more preferably 0.01% to 5% by mass with respect to the total mass of the photosensitive composition layer.

[Aliphatic Thiol Compound]

It is preferable that the photosensitive composition layer includes an aliphatic thiol compound.

By incorporating the aliphatic thiol compound into the photosensitive composition layer, the aliphatic thiol compound undergoes an ene-thiol reaction with a radically polymerizable compound having an ethylenically unsaturated group, whereby a film formed is suppressed from being cured and shrunk, and the stress is thus relieved.

As the aliphatic thiol compound, a monofunctional aliphatic thiol compound or a polyfunctional aliphatic thiol compound (that is, a bi- or higher functional aliphatic thiol compound) is preferable.

Among those, as the aliphatic thiol compound, for example, a polyfunctional aliphatic thiol compound is preferable from the viewpoint of adhesiveness (in particular, adhesiveness after exposure) of a pattern thus formed.

In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, a molecular weight of the polyfunctional aliphatic thiol compound is more preferably 100 to 1,500 and still more preferably 150 to 1,000.

The number of functional groups of the polyfunctional aliphatic thiol compound is, for example, preferably 2 to 10, more preferably 2 to 8, and still more preferably 2 to 6 from the viewpoint of the adhesiveness of a pattern thus formed.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,4-bis(3-mercaptobutyryloxy)butane, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among those, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, p-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive composition layer may include only one kind of aliphatic thiol compound, or may contain two or more kinds of aliphatic thiol compounds.

In a case where the photosensitive composition layer includes the aliphatic thiol compound, a content of the aliphatic thiol compound is preferably 5% by mass or more, more preferably 5% to 50% by mass, still more preferably 5% to 30% by mass, and particularly preferably 8% to 20% by mass with respect to the total mass of the photosensitive composition layer.

[Blocked Isocyanate Compound]

It is preferable that the photosensitive composition layer includes a blocked isocyanate compound. The blocked isocyanate compound contributes to improvement of hardness of a pattern thus formed.

Since the blocked isocyanate compound reacts with a hydroxyl group and a carboxyl group, for example, in a case where at least one of the binder polymer or the radically polymerizable compound having an ethylenically unsaturated group has at least one of a hydroxyl group or a carboxyl group, hydrophilicity of the formed film tends to decrease, and the function as a protective film tends to be strengthened. Furthermore, the blocked isocyanate compound refers to a “compound having a structure in which the isocyanate group of isocyanate is protected (so-called masked) with a blocking agent”.

The dissociation temperature of the blocked isocyanate compound is preferably 100° C. to 160° C., and more preferably 110° C. to 150° C.

In the present disclosure, the “dissociation temperature of the blocked isocyanate compound” means a temperature at an endothermic peak accompanied with a deprotection reaction of the blocked isocyanate compound, in a case where the measurement is performed by differential scanning calorimetry (DSC) analysis using a differential scanning calorimeter. As the differential scanning calorimeter, for example, a differential scanning calorimeter (model: DSC6200) manufactured by Seiko Instruments Inc. can be suitably used. It should be noted that the differential scanning calorimeter is not limited to the differential scanning calorimeter described above.

Examples of the blocking agent having a dissociation temperature of 100° C. to 160° C. include active methylene compounds [diester malonates (such as dimethyl malonate, diethyl malonate, di-n-butyl malonate, and di-2-ethylhexyl malonate)], and oxime compounds (compound having a structure represented by —C(═N—OH)— in a molecule, such as formaldoxime, acetoaldoxime, acetoxime, methyl ethyl ketoxime, and cyclohexanone oxime). Among those, for example, the oxime compound is preferable as the blocking agent blocking agent having a dissociation temperature of 100° C. to 160° C. from the viewpoint of storage stability.

From the viewpoint of improvement of brittleness of a film, improvement of adhesive force onto an object to be transferred, and the like, the blocked isocyanate compound preferably has an isocyanurate structure. The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound preferably has a polymerizable group, and more preferably has a radically polymerizable group from the viewpoint of the hardness of a pattern thus formed.

Examples of the polymerizable group include a (meth)acryloxy group, a (meth)acrylamide group, an ethylenically unsaturated group such as styryl group, and an epoxy group such as a glycidyl group. Among those, as the polymerizable group, from the viewpoint of surface shape of the surface of a pattern thus obtained, a development speed, and reactivity, an ethylenically unsaturated group is preferable, and a (meth)acryloxy group is more preferable.

As the blocked isocyanate compound, a commercially available product can be used. Examples of the commercially available product of the blocked isocyanate compound include KARENZ (registered trademark) AOI-BM, KARENZ (registered trademark) MOI-BM, KARENZ (registered trademark) AOI-BP, KARENZ (registered trademark) MOI-BP, and the like [all manufactured by SHOWA DENKO K.K.], and block-type DURANATE series [for example, DURANATE (registered trademark) TPA-B80E, manufactured by Asahi Kasei Corporation].

The photosensitive composition layer may include only one kind of blocked isocyanate compound, or may include two or more kinds of blocked isocyanate compounds.

In a case where the photosensitive composition layer includes the blocked isocyanate compound, a content of the blocked isocyanate compound is preferably 1% to 50% by mass, and more preferably 5% to 30% by mass with respect to the total mass of the photosensitive composition layer.

[Surfactant]

The photosensitive composition layer may include a surfactant.

Examples of the surfactant include the surfactants described in paragraph [0017] of JP4502784B and paragraphs [0060] to [0071] of JP2009-237362A.

As the surfactant, a nonionic surfactant, a fluorine-based surfactant, or a silicone-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90, R-94, RS-72-K, and DS-21 (all manufactured by DIC Corporation);
FLUORAD FC430, FC431, and FC171 (all manufactured by Sumitomo 3M Ltd.);
SURFLON S-382, SC-101, SC-103, SC-104, SC-105, SC-1068, SC-381, SC-383, S-393, and KH-40 (all manufactured by Asahi Glass Co., Ltd.);
PolyFox PF636, PF656, PF6320, PF6520, and PF7002 (all manufactured by OMNOVA Solutions Inc.); and
FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all manufactured by NEOS Co., Ltd.).

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant.

A block polymer can also be used as the fluorine-based surfactant. As the fluorine-based surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group).

As the fluorine-based surfactant, a fluorine-containing polymer having an ethylenically unsaturated bond-containing group in the side chain can be used. Examples thereof include MEGAFACE RS-101, RS-102, RS-718K, and RS-72-K (all manufactured by DIC Corporation.

In addition, from the viewpoint of improving environmental suitability, as the fluorine-based surfactant, a surfactant derived from a substitute material for a compound having a linear perfluoroalkyl group having 7 or more carbon atoms, such as perfluorooctanoic acid (PFOA) and perfluorooctanesulfonic acid (PFOS), is preferably used.

Examples of the silicone-based surfactant include a linear polymer consisting of a siloxane bond and a modified siloxane polymer with an organic group introduced in the side chain or the terminal.

In addition, examples of a commercially available product of the silicone-based surfactant include: DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Corporation); X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all manufactured by Shin-Etsu Silicones Co., Ltd.); F-4440, TSF-4300, TSF-4445, TSF-4460, and TSF-4452 (all manufactured by Momentive Performance Materials Inc.); and BYK307, BYK323, and BYK330 (all manufactured by BYK-Chemie Japan K. K.).

Examples of the non-ionic surfactant that can be used include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and a sorbitan fatty acid ester.

Examples of commercially available nonionic surfactants include:
PLURONIC L10, L31, L61, L62, 10R5, 17R2, and 25R2 (all manufactured by BASF);
TETRONIC 304, 701, 704, 901, 904, and 150R1 (all manufactured by BASF);
SOLSEPERSE 20000 (manufactured by Lubrizol Japan Ltd.);
NCW-101, NCW-1001, and NCW-1002 (all manufactured by FUJIFILM Wako Pure Chemical Corporation);
PIONIN D-6112, D-6112-W, and D-6315 (all manufactured by Takemoto Oil & Fat Co., Ltd.); and
OLFINE E1010, and SURFYNOL 104, 400, and 440 (all manufactured by Nissin Chemical Industry Co., Ltd.).

The surfactants may be used alone or in combination of two or more kinds thereof.

In a case where the photosensitive composition layer includes the surfactant, a content of the surfactant is preferably 0.01% to 3.0% by mass, more preferably 0.05% to 1.0% by mass, and still more preferably 0.10% to 0.80% by mass with respect to the total mass of the photosensitive composition layer.

[Hydrogen Donating Compound]

It is preferable that the photosensitive composition layer includes a hydrogen donating compound. The hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537A), JP1989-033104A (JP-S64-033104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-042965B (JP-S48-042965B) (tributyl tin acetate and the like), a hydrogen donor described in JP1980-034414B (JP-S55-034414B), and a sulfur compound described in JP1994-308727A (JP-H06-308727A) (trithiane and the like).

The photosensitive composition layer may include only one kind of hydrogen donating compound, or may include two or more kinds of hydrogen donating compounds.

In a case where the photosensitive composition layer includes the hydrogen donating compound, a content of the hydrogen donating compound is preferably 0.01% to 10% by mass, more preferably 0.03% to 5% by mass, and still more preferably 0.05% to 3% by mass with respect to the total mass of the photosensitive composition layer from the viewpoint of improving a curing rate by balancing the polymerization growth rate and the chain transfer.

[Other Components]

The photosensitive composition layer may include a component other than the above-mentioned components (hereinafter also referred to as “other components”). Examples of the other components include particles (for example, metal oxide particles), a sensitizer, and a colorant. In addition, examples of the other components include a thermal polymerization inhibitor described in paragraph [0018] of JP4502784B and other additives described in paragraphs [0058] to [0071] of JP2000-310706A.

The photosensitive composition layer may include particles for the purpose of adjusting refractive index, light-transmitting property, and the like. Examples of the particles include metal oxide particles.

Examples of a metal in the metal oxide particles also include semimetal such as B, Si, Ge, As, Sb, and Te.

From a viewpoint of transparency of a pattern, an average primary particle diameter of the particles is, for example, preferably 1 to 200 nm, and more preferably 3 to 80 nm. The average primary particle diameter of the particles is calculated by measuring particle diameters of 200 random particles using an electron microscope, and arithmetically averaging the measurement results. Furthermore, in a case where the shape of the particle is not a spherical shape, the longest side is set as the particle diameter.

The photosensitive composition layer may include only one kind of particles, or may include two or more kinds of particles. In addition, in a case where the photosensitive composition layer includes the particles, it may include only one kind of particles having different metal types, sizes, and the like, or may include two or more kinds thereof.

It is preferable that the photosensitive composition layer does not include particles, or the content of the particles is more than 0% by mass to 35% by mass or less with respect to the total mass of the photosensitive composition layer; it is more preferable that the photosensitive composition layer does not include particles, or the content of the particles is more than 0% by mass to 10% by mass or less with respect to the total mass of the photosensitive composition layer; it is still more preferable that the photosensitive composition layer does not include particles, or the content of the particles is more than 0% by mass to 5% by mass or less with respect to the total mass of the photosensitive composition layer; it is particularly preferable that the photosensitive composition layer does not include particles, or the content of the particles is more than 0% by mass to 1% by mass or less with respect to the total mass of the photosensitive composition layer; and it is the most preferable that the photosensitive composition layer does not include particles.

The photosensitive composition layer may include a trace amount of a colorant (for example, a pigment and a dye), but for example, from the viewpoint of transparency, it is preferable that the photosensitive composition layer does not substantially include the colorant.

In a case where the photosensitive composition layer includes the colorant, the content of the colorant is preferably less than 1% by mass, and more preferably less than 0.1% by mass with respect to the total mass of the photosensitive composition layer.

[Impurities and the like]

The photosensitive composition layer may include a predetermined amount of impurities.

Examples of the impurities include sodium, potassium, magnesium, calcium, iron, manganese, copper, aluminum, titanium, chromium, cobalt, nickel, zinc, tin, halogen, and ions of these. Among these, the halide ion, the sodium ion, and the potassium ion are easily mixed as impurities, and thus, the following content is preferable.

A content of the impurities in the photosensitive composition layer is preferably 80 ppm or less, more preferably 10 ppm or less, and still more preferably 2 ppm or less on a mass basis. The content of impurities in the photosensitive composition layer may be 1 ppb or more or 0.1 ppm or more on a mass basis.

Examples of a method for keeping the impurities in the range include selecting a raw material having a low content of impurities as a raw material for the photosensitive composition layer, preventing the impurities from being mixed in a case of forming the photosensitive composition layer, and washing and removing the impurities. By such a method, the amount of impurities can be kept within the range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in the photosensitive composition layer. A content of these compounds in the photosensitive composition layer is preferably 100 ppm or less, more preferably 20 ppm or less, and still more preferably 4 ppm or less on a mass basis. The lower limit may be 10 ppb or more or 100 ppb or more on a mass basis. The content of these compounds can be suppressed in the same manner as in the metal as impurities. In addition, the compounds can be quantified by a known measurement method.

From the viewpoint of reliability and a laminating property, the content of water in the photosensitive composition layer is preferably 0.01% to 1.0% by mass, and more preferably 0.05% to 0.5% by mass.

[Thickness of Photosensitive Composition Layer]

A thickness of the photosensitive composition layer is not particularly limited, but is preferably 10.0 μm or less, and more preferably 8.0 μm or less.

The lower limit of the thickness of the photosensitive composition layer is not limited. As the thickness of the photosensitive composition layer is smaller, the bend resistance can be improved. From the viewpoint of manufacturing suitability, the lower limit of the thickness of the photosensitive composition layer is preferably 0.05 μm or more. The lower limit of the thickness of the photosensitive composition layer is preferably 0.5 μm or more, and more preferably 1.1 μm or more from the viewpoint of improving the protective property of the transparent resin layer.

The thickness of the photosensitive composition layer is obtained as an average value at 5 random points measured by cross-section observation with a scanning electron microscope (SEM).

[Refractive Index of Photosensitive Composition Layer]

A refractive index of the photosensitive composition layer is preferably 1.47 to 1.56, and more preferably 1.49 to 1.54.

[Color of Photosensitive Composition Layer]

The photosensitive composition layer is preferably achromatic. In an L*a*b* color system, the a* value of the photosensitive composition layer is preferably −1.0 to 1.0, and the b* value of the photosensitive composition layer is preferably −1.0 to 1.0.

[Moisture Permeability of Photosensitive Composition Layer]

A moisture permeability of a pattern obtained by curing the photosensitive composition layer (a cured film of the photosensitive composition layer) at a film thickness of 40 μm is preferably 500 g/m²/24 hr or less, more preferably 300 g/m²/24 hr or less, and still more preferably 100 g/m²/24 hr or less from the viewpoint of rust preventing properties.

Furthermore, the moisture permeability is measured with a cured film by curing the photosensitive composition layer by exposing the photosensitive composition layer with an i-line at an exposure amount of 300 mJ/cm² and then performing post-baking at 145° C. for 30 minutes.

<Other Layers>

The transfer film may include a layer other than the above-mentioned temporary support and photosensitive composition layer.

[Protective Film]

The transfer film may have a protective film for protecting the photosensitive composition layer on a surface opposite to the temporary support.

The protective film is preferably a resin film, a resin film having heat resistance and solvent resistance can be used, and examples thereof include polyolefin films such as a polypropylene film and a polyethylene film, polyester films such as a polyethylene terephthalate film, polycarbonate films, and polystyrene films. In addition, a resin film composed of the same material as the above-mentioned temporary support may be used as the protective film.

The thickness of the protective film is preferably 1 to 100 μm, more preferably 5 to 50 μm, still more preferably 5 to 40 μm, and particularly preferably 15 to 30 μm. The thickness of the protective film is preferably 1 μm or more from the viewpoint of excellent mechanical hardness, and is preferably 100 μm or less from viewpoint of relatively low cost.

In addition, in the protective film, the number of fisheyes with a diameter of 80 μm or more in the protective film is preferably 5 pieces/m² or less.

Incidentally, the “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less.

This makes it possible to suppress defects generated in a case where unevenness caused by the particles included in the protective film is transferred to the photosensitive composition layer and the like.

From the viewpoint of imparting a take-up property, an arithmetic average roughness Ra of a surface of the protective film on a side opposite to the photosensitive composition layer is preferably 0.01 μm or more, more preferably 0.02 μm or more, and still more preferably 0.03 μm or more. On the other hand, Ra is preferably less than 0.50 μm, more preferably 0.40 μm or less, and still more preferably 0.30 μm or less.

From the viewpoint of suppressing defects during transfer, the surface roughness Ra of a surface on the photosensitive composition layer side in the protective film is preferably 0.01 μm or more, more preferably 0.02 μm or more, and still more preferably 0.03 μm or more. On the other hand, Ra is preferably less than 0.50 μm, more preferably 0.40 μm or less, and still more preferably 0.30 μm or less.

[Refractive Index-Adjusting Layer]

The transfer film may have a refractive index-adjusting layer. The position of the refractive index-adjusting layer is not particularly limited, but the refractive index-adjusting layer is preferably arranged in contact with the photosensitive composition layer. Above all, it is preferable that the transfer film has the temporary support, the photosensitive composition layer, and the refractive index-adjusting layer in this order.

Furthermore, in a case where the transfer film further has the above-mentioned protective film, it is preferable that the transfer film has the temporary support, the photosensitive composition layer, the refractive index-adjusting layer, and the protective film in this order.

As the refractive index-adjusting layer, a known refractive index-adjusting layer can be applied. Examples of a material included in the refractive index-adjusting layer include a binder and particles.

Examples of the binder include the alkali-soluble resin explained in the section of “Photosensitive Composition Layer” above.

Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index-adjusting layer preferably includes a metal oxidation inhibitor. In a case where the refractive index-adjusting layer includes a metal oxidation inhibitor, oxidation of metal in contact with the refractive index-adjusting layer can be suppressed.

As the metal oxidation inhibitor, for example, a compound having an aromatic ring including a nitrogen atom in the molecule is preferable. Examples of the metal oxidation inhibitor include imidazole, benzimidazole, tetrazole, mercaptothiadiazole, and benzotriazole.

A refractive index of the refractive index-adjusting layer is preferably 1.60 or more, and more preferably 1.63 or more.

The upper limit of the refractive index of the refractive index-adjusting layer is preferably 2.10 or less, and more preferably 1.85 or less.

A thickness of the refractive index-adjusting layer is preferably 500 nm or less, more preferably 110 nm or less, and still more preferably 100 nm or less.

The thickness of the refractive index-adjusting layer is preferably 20 nm or more, and more preferably 50 nm or more.

The thickness of the refractive index-adjusting layer is obtained as an average value at 5 random points measured by cross-section observation with a scanning electron microscope (SEM).

<Method for Manufacturing Transfer Film>

The method for producing a transfer film of an embodiment of the present invention is not particularly limited, and known methods can be used.

Above all, a method of applying a photosensitive composition onto a temporary support, followed by performing a drying treatment as necessary, to form a photosensitive composition layer is preferable from the viewpoint that the productivity is excellent.

The method will be described below in detail.

The photosensitive composition preferably includes the above-mentioned components (for example, the polymerizable compound, the alkali-soluble resin, and the photopolymerization initiator) constituting the photosensitive composition layer, and a solvent.

As the solvent, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

In addition, as the solvent, an organic solvent (high-boiling-point solvent) having a boiling point of 180° C. to 250° C. can also be used, as necessary.

The photosensitive composition includes include only one kind of solvent, or may include two or more kinds of solvents.

In a case where the photosensitive composition includes the solvent, a total solid content of the photosensitive composition is preferably 5% to 80% by mass, more preferably 5% to 40% by mass, and still more preferably 5% to 30% by mass to the total mass of the photosensitive composition.

In a case where the photosensitive composition includes the solvent, for example, from the viewpoint of coatability, the viscosity of the photosensitive composition at 25° C. is preferably 1 to 50 mPa-s, more preferably 2 to 40 mPa-s, and still more preferably 3 to 30 mPa-s. The viscosity is measured using a viscometer. As the viscometer, for example, a viscometer (product name: VISCOMETER TV-22) manufactured by Toki Sangyo Co. Ltd. can be suitably used. However, the viscometer is not limited to the above-described viscometer.

In a case where the photosensitive composition includes the solvent, a surface tension of the photosensitive composition at 25° C. is preferably 5 to 100 mN/m, more preferably 10 to 80 mN/m, and still more preferably 15 to 40 mN/m from a viewpoint of surface tension. The surface tension is measured using a tensiometer. As the tensiometer, for example, a tensiometer (product name: Automatic Surface Tensiometer CBVP-Z) manufactured by Kyowa Interface Science Co., Ltd. can be suitably used. It should be noted that the tensiometer is not limited to the above-described tensiometer.

Examples of the method for applying the photosensitive composition include a printing method, a spray coating method, a roll coating method, a bar coating method, a curtain coating method, a spin coating method, and a die coating method (that is, a slit coating method).

Examples of the drying method include natural drying, heating drying, and drying under reduced pressure. The above-described methods can be adopted alone or in combination of two or more thereof.

In the present disclosure, the “drying” means removing at least a part of the solvent included in the composition.

In a case where the transfer film has a refractive index-adjusting layer on the photosensitive composition layer, for example, a composition for forming the refractive index-adjusting layer is applied onto the photosensitive composition layer, and dried as necessary, to form the refractive index-adjusting layer.

In addition, in a case where the transfer film has a protective film, the transfer film can be produced by affixing the protective film to the photosensitive composition layer.

A method for affixing the protective film to the photosensitive composition layer is not particularly limited, and examples thereof include known methods.

Examples of a device for affixing the protective film to the photosensitive composition layer include known laminators such as a vacuum laminator and an auto-cut laminator.

It is preferable that the laminator is equipped with any heatable roller such as a rubber roller and can perform pressing and heating.

<Method for Producing Laminate]

By using the above-mentioned transfer film, the photosensitive composition layer can be transferred to an object to be transferred.

The object to be transferred is not particularly limited, but a substrate having a conductive layer is preferable.

As the method for producing a laminate, a method for producing a laminate, including an affixing step of affixing the transfer film to a substrate having a conductive layer so that the photosensitive composition layer side of the transfer film faces the substrate, to obtain a substrate with a photosensitive composition layer, an exposing step of pattern-exposing the photosensitive composition layer with light having a wavelength of 365 nm as a main wavelength, a developing step of developing the exposed photosensitive composition layer to form a pattern, and a post-exposing step of irradiating the pattern with light with which the second photopolymerization initiator is photosensitized, in which a peeling step of peeling the temporary support from the substrate with a photosensitive composition layer is included between the affixing step and the exposing step, or between the exposing step and the developing step.

In the laminate obtained by the procedure, the pattern is arranged on the substrate having the conductive layer.

Hereinafter, the procedure of each step for the laminate will be described in detail.

[Affixing Step]

The affixing step is a step of affixing the transfer film to a substrate having a conductive layer so that the photosensitive composition layer side of the transfer film faces the substrate, to obtain a substrate with a photosensitive composition layer. That is, the transfer film and the substrate are affixed to each other so that the photosensitive composition layer faces the substrate side rather than the support in the transfer film. By this affixing, the photosensitive composition layer and the temporary support are arranged on the substrate having the conductive layer.

In the affixing, it is preferable that the conductive layer and the surface of the photosensitive composition layer are pressure-bonded so that the both are in contact with each other. In the aspect, the pattern obtained after exposure and development can be suitably used as an etching resist at the time of etching the conductive layer.

The pressure-bonding method is not particularly limited, and known transfer methods and laminating methods can be used. Among those, it is preferable to superimpose a surface of the photosensitive composition layer on a substrate having a conductive layer, followed by pressurizing and heating with a roll or the like.

A known laminator such as a vacuum laminator and an auto-cut laminator can be used for the affixing.

The substrate having a conductive layer has a conductive layer on the substrate, and any layer may be formed as necessary. That is, the substrate having the conductive layer is a conductive substrate having at least a substrate and a conductive layer arranged on the substrate.

Examples of the substrate include a resin substrate, a glass substrate, and a semiconductor substrate.

Preferred aspects of the substrate are described, for example, in paragraph [0140] of WO2018/155193A, the contents of which are incorporated herein by reference.

As the conductive layer, at least one layer selected from the group consisting of a metal layer, a conductive metal oxide layer, a graphene layer, a carbon nanotube layer, and a conductive polymer layer is preferable from the viewpoint of conductivity and a fine wire forming property.

In addition, only one conductive layer may be arranged, or two or more conductive layers may be arranged on the substrate. In a case where two or more conductive layers are arranged, it is preferable to have conductive layers made of different materials.

Preferred aspects of the conductive layers are described, for example, in paragraph [0141] of WO2018/155193A, the contents of which are incorporated herein by reference.

From the viewpoint of applying the obtained laminate to a touch panel, it is preferable that the conductive layer has a sensor electrode part for a touch panel and a lead wire part conducting with the sensor electrode for a touch panel. That is, the substrate having the conductive layer is preferably a substrate having a sensor electrode part for a touch panel and a lead wire part conducting with the sensor electrode for a touch panel.

[Exposing Step]

The exposing step is a step of pattern-exposing the photosensitive composition layer with light having a wavelength of 365 nm as a main wavelength. By carrying out the present step, the first photopolymerization initiator having high photosensitivity at a wavelength of 365 nm is photosensitized, and the polymerizable compound is polymerized.

Furthermore, here, the “pattern exposure” refers to exposure in a form of performing the exposure in a patterned type, that is, a form in which an exposed portion and an unexposed portion are present.

Detailed arrangement and specific size of the pattern in the pattern exposure are not particularly limited. Incidentally, a pattern formed by the developing step which will be described later preferably includes thin lines having a width of 20 μm or less, and more preferably includes thin lines having a width of 10 μm or less.

As a light source for the pattern exposure, any light source having a wavelength of at least 365 nm as a main wavelength (exposure light) can be appropriately selected and used.

Furthermore, the main wavelength is a wavelength having the highest intensity in the exposure light.

Examples of the light source include various lasers, a light emitting diode (LED), an ultra-high pressure mercury lamp, a high pressure mercury lamp, and a metal halide lamp.

The exposure amount is preferably 5 to 200 mJ/cm², and more preferably 10 to 100 mJ/cm².

Suitable aspects of the light source, the exposure amount, and the exposing method used for the exposure are described in, for example, paragraphs [0146] and [0147] of WO2018/155193A, the contents of which are incorporated herein by reference.

Moreover, in a case where the exposing step is carried out before a peeling step which will be described later is carried out, the exposure is performed in a state where the temporary support remains on the photosensitive composition layer.

In a case where exposure is performed from the temporary support side, a part of light for the exposure (particularly the light on a short wavelength side) is easily absorbed by the temporary support, and as a result, it is easy that light on a long wavelength side of the light emitted from the light source reaches the photosensitive composition.

That is, by carrying out the peeling step between the exposing step and the developing step which will be described later, it is easy to realize exposure conditions under which the second photopolymerization initiator is less likely to be exposed and the first photopolymerization initiator is easily photosensitized.

[Peeling Step]

The peeling step is a step of peeling the temporary support from the substrate with a photosensitive composition layer between the affixing step and the exposing step, or between the exposing step and the developing step which will be described later.

The peeling method is not particularly limited, and the same mechanism as the cover film peeling mechanism described in paragraphs [0161] and [0162] of JP2010-072589A can be used.

[Developing Step]

The developing step is a step of developing the exposed photosensitive composition layer to form a pattern.

Development of the photosensitive composition layer can be performed using a developer.

As the developer, an alkaline aqueous solution is preferable. Examples of an alkaline compound which can be included in the alkaline aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutylammonium hydroxide, and choline (2-hydroxyethyltrimethyl ammonium hydroxide).

Examples of the developing method include methods such as puddle development, shower development, spin development, and dip development.

Examples of the developer that is suitably used in the present disclosure include the developer described in paragraph [0194] of WO2015/093271A, and examples of the developing method that is suitably used include the developing method described in paragraph [0195] of WO2015/093271A.

[Post-Exposing Step]

The post-exposing step is a step of irradiating the pattern obtained by the developing step with light by which the second photopolymerization initiator is photosensitized. By carrying out the present step, the second photopolymerization initiator which is difficult to be photosensitized and thus remains in the exposing step is photosensitized, and the polymerizable compound is further polymerized to form a pattern having excellent scratch resistance.

As the light source for exposure, any light (exposure light) with which the second photopolymerization initiator is photosensitized can be appropriately selected and used.

Above all, it is preferable to irradiate the second photopolymerization initiator with light including light at the maximum absorption wavelength (exposure light) mentioned above.

The light irradiated in the present step preferably includes light at 313 nm.

Examples of the light source include various lasers, a light emitting diode (LED), an ultra-high pressure mercury lamp, a high pressure mercury lamp, and a metal halide lamp.

The exposure amount is not particularly limited, but is preferably larger than the exposure amount in the exposing step. Specifically, the exposure amount is preferably 100 to 600 mJ/cm², and more preferably 300 to 500 mJ/cm².

A pattern formed by the procedure (a cured film of the photosensitive composition layer) is preferably achromatic. Specifically, in an L*a*b* color system, the a* value of the pattern is preferably −1.0 to 1.0, and the b* value of the pattern is preferably −1.0 to 1.0.

[Other Steps]

The method for producing a laminate of an embodiment of the present invention may include any steps (other steps) other than those described above.

In a case where the transfer film has a protective film, it is preferable that the method has a peeling step of peeling the protective film from the transfer film before the affixing step. In this case, it is preferable to carry out the affixing step so that the exposed surface side (photosensitive composition layer side) exposed in the peeling step is affixed to the above-mentioned substrate having a conductive layer.

The method of peeling the protective film is not particularly limited, and a known method can be adopted. For example, mechanism of peeling a cover film, described in paragraphs [0161] and [0162] of JP2010-072589A can be used.

In addition, the method for producing a laminate of the embodiment of the present invention may include a step (post-baking step) of heating a pattern thus obtained.

The heating temperature during the post-baking step is not particularly limited, but is preferably 110° C. to 180° C.

The method for producing a laminate may have an etching step of etching the conductive layer in a region where the pattern is not arranged in a laminate thus obtained.

In the etching step, the pattern formed from the photosensitive composition layer by the developing step is used as an etching resist to etch the conductive layer.

As a method for the etching treatment, known methods such as methods by dry etching such as the methods described in paragraphs [0209] and [0210] of JP2017-120435A, paragraphs [0048] to [0054] of JP2010-152155A, and the like, and known plasma etching can be applied.

The method for manufacturing the laminate may include a removal step of removing the pattern.

The removal step can be performed as needed, but is preferably performed after the etching step.

The method for removing the pattern is not particularly limited, but examples thereof include a method for removing the pattern by chemical treatment, and it is preferable to use a removing liquid.

Examples of the method for removing the pattern include a method of immersing a laminate having a pattern in a removing liquid under stirring at preferably 30° C. to 80° C., and more preferably 50° C. to 80° C. for 1 to 30 minutes.

Examples of the removing liquid include a removing liquid in inorganic alkali components such as sodium hydroxide and potassium hydroxide, or organic alkali components such as a primary amine compound, a secondary amine compound, a tertiary amine compound, and a quaternary ammonium salt compound are dissolved in water, dimethylsulfoxide, N-methylpyrrolidone, or a mixed solution thereof.

In addition, the removal may be performed by a spray method, a shower method, a paddle method or the like, using the removing liquid.

In addition, the method for producing a laminate may also include the step of reducing visible light reflectance described in paragraph [0172] of WO2019/022089A.

Furthermore, the method for producing a laminate may also include the step of forming a new conductive layer on an insulating film described in paragraph [0172] of WO2019/022089A.

The laminate produced by the method for producing a laminate of the embodiment of the present invention can be applied to various devices. Examples of the device provided with the laminate include input devices; and a touch panel is preferable, and a capacitance type touch panel is more preferable. In addition, the input device can be applied to a display device such as an organic electroluminescence display device and a liquid crystal display device.

In a case where the laminate is applied to a touch panel, it is preferable that a pattern formed from the photosensitive composition layer is used as a protective film for a touch panel electrode. That is, it is preferable that the photosensitive composition layer included in the transfer film is used for formation of an electrode protective film (in particular, a touch panel electrode protective film).

### EXAMPLES

Hereinafter, the present disclosure will be described more specifically with reference to Examples. The material, the amount used, the ratio, the process contents, the process procedure, and the like shown in the following examples can be appropriately changed, within a range not departing from a gist of the present disclosure. Accordingly, the range of the present disclosure is not limited to specific examples shown below. “Parts” is on a mass basis unless otherwise specified.

In the following examples, a weight-average molecular weight of a resin is a weight-average molecular weight obtained by performing polystyrene conversion of a value measured by gel permeation chromatography (GPC). Further, a theoretical acid value was used for the acid value.

<Preparation of Photosensitive Composition>

Photosensitive compositions A-1 to A-32 and A′-1 to A′-3 were prepared so that they had the compositions shown in Tables 1 to 5 below, respectively. Furthermore, the numerical values in the respective component columns in Tables 1 to 5 represent parts by mass.

TABLE 1

| Raw material | | A-1 | A-2 | A-3 | A-4 |
|---|---|---|---|---|---|
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co., Ltd.) | | | | |
| | Monomer with carboxyl group ARONIX | 0.93 | 0.93 | 0.93 | 0.93 |
| | TO-2349 | | | | |
| | (manufactured by Toagosei Co., Ltd.) | | | | |
| | Urethane Acrylate 8UX-015A | — | — | 2.80 | — |
| | (manufactured by | | | | |
| | Taisei Fine Chemical Co., Ltd.) | | | | |
| | A-NOD-N | 1.00 | 2.80 | — | — |
| | (manufactured by | | | | |
| | Shin-Nakamura Chemical Co., Ltd.) | | | | |
| | A-DPH | 1.80 | — | — | — |
| | (manufactured by | | | | |
| | Shin-Nakamura Chemical Co., Ltd.) | | | | |
| Aliphatic thiol | MTNR1 | — | — | — | 2.80 |
| compound | (manufactured by Showa Denko K. K.) | | | | |
| Alkali-soluble | P-1 solution (solid content 36.3% | 42.53 | — | — | — |
| resin | by weight, acid value 95 mgKOH/g, | | | | |
| | Mw 27,000, Mn 15,000) | | | | |
| | P-2 solution (solid content 36.3% | — | 42.53 | — | — |
| | by weight, acid value 95 mgKOH/g, | | | | |
| | Mw 17,000, Mn 6,200) | | | | |
| | P-3: Copolymer of methacrylic | — | — | 15.44 | — |
| | acid/methyl methacrylate/ethyl acrylate | | | | |
| | (compositional ratio (molar ratio) = | | | | |
| | 15/55/30, Mw 60,000, acid value 86 | | | | |
| | mgKOH/g) | | | | |
| | P-4: Copolymer of | — | — | — | 15.44 |
| | methacrylic acid/methyl | | | | |
| | methacrylate/ethyl acrylate | | | | |
| | (compositional ratio (molar ratio) = | | | | |
| | 20/55/25, Mw 60,000, acid value 115 | | | | |
| | mgKOH/g) | | | | |
| Photopolymerization | 1-[9-Ethyl-6-(2-methylbenzyl)- | 0.11 | 0.11 | 0.11 | 0.11 |
| initiator | 9H-carbazol-3-yl]ethanone-1- | | | | |
| | (O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methylbenzyl)- | — | — | — | 0.21 |
| | 1-(4-morpholinophenyl)butan-1-one | | | | |
| | (Irgacure 379EG, manufactured by BASF) | | | | |
| | 4-(Dimethylamino)ethyl benzoate | 0.21 | — | — | — |
| | (manufactured by DAROCUR EDB, BASF) | | | | |
| | 2-Hydroxy-4′-(2-hydroxyethoxy)-2- | — | 0.30 | — | — |
| | methylacetophenone | | | | |
| | (Irgacure 2959, manufactured by BASF) | | | | |
| | 1-(Bipheny]-4-yl)-2-methyl-2- | — | — | 0.21 | — |
| | morpholinopropan-1-one | | | | |
| | (Irgacure 307, manufactured by BASF) | | | | |
| | Phenylbis(2,4,6-trimethylbenzyl)phosphine | — | — | — | — |
| | oxide Irgacure 819, manufactured by BASF) | | | | |
| Blocked isocyanate | Karenz AOI-BM | — | 3.62 | 3.62 | 3.62 |
| compound | (manufactured by Showa Denko K. K.) | | | | |
| | WT32-B75P | 3.62 | — | — | — |
| | (manufactured by Asahi Kasei Corporation) | | | | |
| Additive | N-phenylglycine (manufactured by | — | — | — | — |
| | Tokyo Chemical Industry Co., Ltd.) | | | | |
| | 1,2,4-Triazole (manufactured by | 0.09 | — | — | — |
| | Otsuka Chemical Co., Ltd.) | | | | |
| | Benzimidazole (manufactured by | — | 0.09 | — | — |
| | Tokyo Chemical Industry Co., Ltd.) | | | | |
| | 5-Amino-1H-tetrazole (manufactured by | — | — | 0.09 | — |
| | Tokyo Chemical Industry Co., Ltd.) | | | | |
| | Isonicotinamide (manufactured by | — | — | — | 0.09 |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | — | — |
| | DIC Corporation) | | | | |
| | DOWSIL (registered trademark) 8032 | — | — | 0.16 | 0.16 |
| | Additive (manufactured by Dow | | | | |
| | Corning Toray Co., Ltd.) | | | | |
| Solvent 1 | 1-Methoxy-2-propyl acetate | 3.65 | 3.56 | 50.01 | 30.74 |
| | Methyl ethyl ketone | 40.00 | 40.00 | 20.73 | 40.00 |
| Total (parts by mass) | | 100 | 100 | 100 | 100 |
| Raw material | | A-5 | A-6 | A-7 | A-8 |
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co., Ltd.) | | | | |
| | Monomer with carboxyl group ARONIX | 0.93 | 0.93 | 0.93 | 0.93 |
| | TO-2349 | | | | |
| | (manufactured by Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N | 1.00 | 1.00 | 1.00 | 1.00 |
| | (manufactured by | | | | |
| | Shin-Nakamura Chemical Co., Ltd.) | | | | |
| | A-DPH | 1.80 | 1.80 | 1.80 | 1.80 |
| | (manufactured by | | | | |
| | Shin-Nakamura Chemical Co., Ltd.) | | | | |
| Aliphatic thiol | MTNR1 | — | — | — | — |
| compound | (manufactured by Showa Denko K. K.) | | | | |
| Alkali-soluble | P-1 solution (solid content 36.3% | — | — | — | — |
| resin | by weight, acid value 95 mgKOH/g, | | | | |
| | Mw 27,000, Mn 15,000) | | | | |
| | P-2 solution (solid content 36.3% | 42.53 | 42.53 | 42.53 | 42.53 |
| | by weight, acid value 95 mgKOH/g, | | | | |
| | Mw 17,000, Mn 6,200) | | | | |
| | P-3: Copolymer of methacrylic | — | — | — | — |
| | acid/methyl methacrylate/ethyl acrylate | | | | |
| | (compositional ratio (molar ratio) = | | | | |
| | 15/55/30, Mw 60,000, acid value 86 | | | | |
| | mgKOH/g) | | | | |
| | P-4: Copolymer of | — | — | — | — |
| | methacrylic acid/methyl | | | | |
| | methacrylate,'ethyl acrylate | | | | |
| | (compositional ratio (molar ratio) = | | | | |
| | 20/55/25, Mw 60,000, acid value 115 | | | | |
| | mgKOH/g) | | | | |
| Photopolymerization | 1-[9-Ethyl-6-(2-methylbenzyl)- | 0.11 | — | — | — |
| initiator | 9H-carbazol-3-yl]ethanone-1- | | | | |
| | (O-acetoxime) | | | | |
| | (OXE-02, manufactured by BASF) | | | | |
| | 1-[4-(Phenylthio)phenyl]octane- | — | 0.11 | — | — |
| | 1,2-dione-2-(O-benzyloxime) | | | | |
| | (OXE01, manufactured by BASF) | | | | |
| | (OXE03, manufactured by BASF) | — | — | 0.11 | — |
| | 2-(Dimethylamino)-2-(4-methylbenzyl)- | — | — | — | 0.11 |
| | 1-(4-morpholinophenyl)butan-1-one | | | | |
| | (Irgacure 379EG, manufactured by BASF) | | | | |
| | 4-(Dimethylamino)ethyl benzoate | — | 0.21 | 0.21 | 0.21 |
| | (manufactured by DAROCUR EDB, BASF) | | | | |
| | 2-Hydroxy-4′-(2-hydroxyethoxy)-2- | — | — | — | — |
| | methylacetophenone | | | | |
| | (Irgacure 2959, manufactured by BASF) | | | | |
| | 1-(Bipheny]-4-yl)-2-methyl-2- | — | — | — | — |
| | morpholinopropan-1-one | | | | |
| | (Irgacure 307, manufactured by BASF) | | | | |
| | Phenylbis(2,4,6-trimethylbenzyl)phosphine | 0.21 | — | — | — |
| | oxide Irgacure 819, manufactured by BASF) | | | | |
| Blocked isocyanate | Karenz AOI-BM | — | — | — | — |
| compound | (manufactured by Showa Denko K. K.) | | | | |
| | WT32-B75P | 3.62 | 3.62 | 3.62 | 3.62 |
| | (manufactured by Asahi Kasei Corporation) | | | | |
| Additive | N-phenylglycine (manufactured by | — | — | — | — |
| | Tokyo Chemical Industry Co., Ltd.) | | | | |
| | 1,2,4-Triazole (manufactured by | 0.09 | 0.09 | 0.09 | 0.09 |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) 8032 | — | — | — | — |
| | Additive (manufactured by Dow | | | | |
| | Corning Toray Co., Ltd.) | | | | |
| Solvent 1 | 1-Methoxy-2-propyl acetate | 3.65 | 3.65 | 3.65 | 3.65 |
| | Methyl ethyl ketone | 40.00 | 40.00 | 40.00 | 40.00 |

| | | | | |
|---|---|---|---|---|
| Total (parts by mass) | 100 | 100 | 100 | 100 |

TABLE 2

| Raw material | | A-9 | A-10 | A-11 | A-12 |
|---|---|---|---|---|---|
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co., Ltd.) | | | | |
| | Monomer with carboxyl group | 0.93 | 0.93 | 0.93 | 0.93 |
| | ARONIX TO-2349 | | | | |
| | (manufactured by Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N (manufactured by | 1.00 | 1.00 | 1.00 | 1.00 |
| | Shin-Nakamura Chemical Co., Ltd.) | | | | |
| | A-DPH (manufactured by | 1.80 | 1.80 | 1.80 | 1.80 |
| | Shin-Nakamura Chemical Co., Ltd.) | | | | |
| Aliphatic thiol | MTNR1 | — | — | — | — |
| compound | (manufactured by Showa Denko K. K.) | | | | |
| Alkali-soluble | P-1 solution (solid content | 42.53 | 42.53 | 42.53 | 42.53 |
| resin | 36.3% by weight, acid value | | | | |
| | 95 mgKOH/g. Mw 27,000, Mn 15,000) | | | | |
| | P-2 solution (solid content | — | — | — | — |
| | 36.3% by weight, acid value | | | | |
| | 95 mgKOH/g. Mw 17,000, Mn 6,200) | | | | |
| | P-3: Copolymer of methacrylic | — | — | — | — |
| | acid/methyl methacrylate/ethyl acrylate | | | | |
| | (compositional ratio | | | | |
| | (molar ratio) = 15/55/30, | | | | |
| | Mw 60,000, acid value 86 mgKOH/g) | | | | |
| | P-4: Copolymer of | — | — | — | — |
| | methacrylic acid/methyl | | | | |
| | methacrylate/ethyl acrylate | | | | |
| | (compositional ratio | | | | |
| | (molar ratio) = 20/55/25, | | | | |
| | Mw 60,000, acid value 115 mgKOH/g) | | | | |
| Photopolymerization | 1-[9-Ethyl-6-(2-methylbenzyl)- | 0.05 | 0.20 | 0.11 | 0.06 |
| initiator | 9H-carbazol-3-yl]ethanone-1- | | | | |
| | (O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methy]benzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | 0.21 | 0.21 | 0.40 | 0.11 |
| | (manufactured by DAROCUR EDB, BASF) | | | | |
| | 2-Hydroxy-4′-(2-hydroxyethoxy)- | — | — | — | — |
| | 2-methylacetophenone | | | | |
| | (Irgacure 2959, manufactured by BASF) | | | | |
| | 1-(Biphenyl-4-yl)-2-methyl-2- | — | — | — | — |
| | morpholinopropan-l-one | | | | |
| | (Irgacure 307, manufactured by BASF) | | | | |
| | Phernylbis(2,4,6-trimethylbenzyl)phosphine | — | — | — | — |
| | oxide (Irgacure 819, manufactured by BASF) | | | | |
| Blocked | Karenz AOI-BM | — | — | — | — |
| isocyanate | (manufactured by Showa Denko K. K.) | | | | |
| compound | WT32-B75P | 3.62 | 3.62 | 3.62 | 3.62 |
| | (manufactured by Asahi Kasei Corporation) | | | | |
| Additive | N-phenylglycine (manufactured by | — | — | — | — |
| | Tokyo Chemical Industry Co., Ltd.) | | | | |
| | 1,2,4-Triazole (manufactured by | 0.09 | 0.09 | 0.09 | 0.09 |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 8032 Additive | | | | |
| | (manufactured by Dow Corning | | | | |
| | Toray Co., Ltd.) | | | | |
| Solvent 1 | 1-Methoxy-2-propyl acetate | 3.71 | 3.56 | 3.46 | 3.80 |
| | Methyl ethyl ketone | 40.00 | 40.00 | 40.00 | 40.00 |
| Total (parts by mass) | | 100 | 100 | 100 | 100 |
| Raw material | | A-13 | A-14 | A-15 | A-16 |
| Polymerizable | Tricyclodecane dimethanol diacrylate | — | 4.93 | 6.16 | 5.60 |
| compound | (A-DCP, manufactured by | | | | |
| | Shin-Nakamura Chemical Co., Ltd.) | | | | |
| | Monomer with carboxyl group | — | 0.82 | 1.02 | 0.93 |
| | ARONIX TO-2349 | | | | |
| | (manufactured by Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N (manufactured by | 5.60 | 0.88 | 1.10 | 1.00 |
| | Shin-Nakamura Chemical Co., Ltd.) | | | | |
| | A-DPH (manufactured by | 3.73 | 1.58 | 1.98 | 1.80 |
| | Shin-Nakamura Chemical Co., Ltd.) | | | | |
| Aliphatic thiol | MTNR1 | — | — | — | — |
| compound | (manufactured by Showa Denko K. K.) | | | | |
| Alkali-soluble | P-1 solution (solid content | 42.53 | 45.62 | 39.97 | 42.53 |
| resin | 36.3% by weight, acid value | | | | |
| | 95 mgKOH/g. Mw 27,000, Mn 15,000) | | | | |
| | P-2 solution (solid content | — | — | — | — |
| | 36.3% by weight, acid value | | | | |
| | 95 mgKOH/g. Mw 17,000, Mn 6,200) | | | | |
| | P-3: Copolymer of methacrylic | — | — | — | — |
| | acid/methyl methacrylate/ethyl acrylate | | | | |
| | (compositional ratio | | | | |
| | (molar ratio) = 15/55/30, | | | | |
| | Mw 60,000, acid value 86 mgKOH/g) | | | | |
| | P-4: Copolymer of | — | — | — | — |
| | methacrylic acid/methyl | | | | |
| | methacrylate/ethyl acrylate | | | | |
| | (compositional ratio | | | | |
| | (molar ratio) = 20/55/25, | | | | |
| | Mw 60,000, acid value 115 mgKOH/g) | | | | |
| Photopolymerization | 1-[9-Ethyl-6-(2-methylbenzyl)- | 0.20 | 0.11 | 0.11 | 0.11 |
| initiator | 9H-carbazol-3-yl]ethanone-1- | | | | |
| | (O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methy]benzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | 0.30 | 0.21 | 0.21 | 0.21 |
| | (manufactured by DAROCUR EDB, BASF) | | | | |
| | 2-Hydroxy-4′-(2-hydroxyethoxy)- | — | — | — | — |
| | 2-methylacetophenone | | | | |
| | (Irgacure 2959, manufactured by BASF) | | | | |
| | 1-(Biphenyl-4-yl)-2-methyl-2- | — | — | — | — |
| | morpholinopropan-l-one | | | | |
| | (Irgacure 307, manufactured by BASF) | | | | |
| | Phernylbis(2,4,6-trimethylbenzyl)phosphine | — | — | — | — |
| | oxide (Irgacure 819, manufactured by BASF) | | | | |
| Blocked | Karenz AOI-BM | — | — | — | — |
| isocyanate | (manufactured by Showa Denko K. K.) | | | | |
| compound | WT32-B75P | 3.62 | 3.62 | 3.62 | — |
| | (manufactured by Asahi Kasei Corporation) | | | | |
| Additive | N-phenylglycine (manufactured by | — | — | — | — |
| | Tokyo Chemical Industry Co., Ltd.) | | | | |
| | 1,2,4-Triazole (manufactured by | 0.09 | 0.09 | 0.09 | — |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.30 | — |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 8032 Additive | | | | |
| | (manufactured by Dow Corning | | | | |
| | Toray Co., Ltd.) | | | | |
| Solvent 1 | 1-Methoxy-2-propyl acetate | 3.47 | 1.68 | 5.28 | 7.66 |
| | Methyl ethyl ketone | 40.00 | 40.00 | 40.00 | 40.00 |

| | | | | |
|---|---|---|---|---|
| Total (parts by mass) | 100 | 100 | 100 | 100 |

TABLE 3

| Raw material | | A-17 | A-18 | A-19 | A-20 |
|---|---|---|---|---|---|
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co.. Ltd.) | | | | |
| | Monomer with carboxyl group | 0.93 | 0.93 | 0.93 | 0.93 |
| | ARONIX TO-2349 | | | | |
| | (manufactured by | | | | |
| | Toagosei Co., Ltd.) | | | | |
| | Urethane Acrylate 8UX-015A | — | — | 2.80 | — |
| | (manufactured by | | | | |
| | Taisei Fine Chemical Co., Ltd.) | | | | |
| | A-NOD-N | 1.00 | 2.80 | — | — |
| | (manufactured by | | | | |
| | Shin-Nakamura Chemical Co., Ltd.) | | | | |
| | A-DPH | 1.80 | — | — | — |
| | (manufactured by | | | | |
| | Shin-Nakamura Chemical Co., Ltd.) | | | | |
| Aliphatic thiol | MTNR1 | — | — | — | 2.80 |
| compound | (manufactured by Showa Denko K. K.) | | | | |
| | P-1 solution (solid | 42.53 | — | — | — |
| | content 36.3% by weight, | | | | |
| | acid value 95 mgKOH/g, Mw | | | | |
| | 27,000, Mn 15,000) | | | | |
| | P-2 solution (solid content | — | 42.53 | — | — |
| | 36.3% by weight, acid value | | | | |
| | 95 mgKOH/g, Mw | | | | |
| | 17,000, Mn 6,200) | | | | |
| Alkali-soluble | P-3: Copolymer of | — | — | 15.44 | — |
| resin | methacrylic acid/methyl | | | | |
| | methacrylate/ethyi acrylate | | | | |
| | (compositional ratio | | | | |
| | (molar ratio) = | | | | |
| | 15/55/30, Mw 60,000, | | | | |
| | acid value 86 mgKOH/g) | | | | |
| | P-4: Copolymer of methacrylic | — | — | — | 15.44 |
| | acid/methyl methacrylate/ethyi acrylate | | | | |
| | (compositional ratio (molar ratio) = | | | | |
| | 20/55/25, Mw 60,000, acid value 115 | | | | |
| | mgKOH/g) | | | | |
| | 1-19-Ethyl-6-(2-methylbenzyl)-9H- | 0.11 | 0.11 | 0.11 | 0.11 |
| | carbazol-3-yl]ethanone-l- | | | | |
| | (O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| Photopolymerization | 2-(Dimethylamino)-2-(4-methylbenzyl)- | — | — | — | 0.21 |
| initiator | 1-(4-morpholinophenyl)butan-1-one | | | | |
| | (Irgacure 379EG, manufactured by BASF) | | | | |
| | 4-(Dimethylamino)ethyl benzoate | 0.21 | — | — | — |
| | (manufactured by DAROCUR EDB, BASF) | | | | |
| | 2-Hydroxy-4′-(2-hydroxyethoxy)-2- | — | 0.30 | — | — |
| | methylacetophenone | | | | |
| | (Irgacure 2959, manufactured by BASF) | | | | |
| | 1-(Biphenyl-4-yl)-2-methyl-2- | — | — | 0.21 | — |
| | morpholinopropan-1-one | | | | |
| | (Irgacure 307, manufactured by BASF) | | | | |
| | Phenylbis(2,4,6-trimethylbenzyl)phosphine | — | — | — | — |
| | oxide | | | | |
| | (Irgacure 819, manufactured by BASF) | | | | |
| Blocked | Karenz AOI-BM | — | 3.62 | 3.62 | 3.62 |
| isocyanate | (manufactured by Showa Denko K. K.) | | | | |
| compound | WT32-B75P | 3.62 | — | — | — |
| | (manufactured by Asahi Kasei Corporation) | | | | |
| Additive | N-phenylglycine (manufactured by | 0.03 | 0.03 | 0.03 | 0.03 |
| | Tokyo Chemical Industry Co., Ltd.) | | | | |
| | 1,2,4-Triazole (manufactured by | 0.09 | — | — | — |
| | Otsuka Chemical Co., Ltd.) | | | | |
| | Benzimidazole (manufactured by | — | 0.09 | — | — |
| | Tokyo Chemical Industry Co., Ltd.) | | | | |
| | 5-Amino-1H-tetrazole (manufactured by | — | — | 0.09 | — |
| | Tokyo Chemical Industry Co., Ltd.) | | | | |
| | Isonicotinamide (manufactured by | — | — | — | 0.09 |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.10 | 0.16 |
| | DIC Corporation) | | | | |
| | DOWSIL (registered trademark) | 0.16 | 0.16 | 0.10 | 0.16 |
| | 8032 Additive | | | | |
| | (manufactured by Dow | | | | |
| | Corning Toray Co., Ltd.) | | | | |
| Solvent 1 | 1-Methoxy-2-propyl acetate | 3.46 | 3.37 | 49.94 | 30.55 |
| | Methyl ethyl ketone | 40.00 | 40.00 | 20.73 | 40.00 |
| Total (parts by mass) | | 100 | 100 | 100 | 100 |
| Raw material | | A-21 | A-22 | A-23 | A-24 |
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co.. Ltd.) | | | | |
| | Monomer with carboxyl group | 0.93 | 0.93 | 0.93 | 0.93 |
| | ARONIX TO-2349 | | | | |
| | (manufactured by | | | | |
| | Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N | 1.00 | 1.00 | 1.00 | 1.00 |
| | (manufactured by | | | | |
| | Shin-Nakamura Chemical Co., Ltd.) | | | | |
| | A-DPH | 1.80 | 1.80 | 1.80 | 1.80 |
| | (manufactured by | | | | |
| | Shin-Nakamura Chemical Co., Ltd.) | | | | |
| Aliphatic thiol | MTNR1 | — | — | — | — |
| compound | (manufactured by Showa Denko K. K.) | | | | |
| | P-1 solution (solid | — | — | — | — |
| | content 36.3% by weight, | | | | |
| | acid value 95 mgKOH/g, Mw | | | | |
| | 27,000, Mn 15,000) | | | | |
| | P-2 solution (solid content | 42.53 | 42.53 | 42.53 | 42.53 |
| | 36.3% by weight, acid value | | | | |
| | 95 mgKOH/g, Mw | | | | |
| | 17,000, Mn 6,200) | | | | |
| Alkali-soluble | P-3: Copolymer of | — | — | — | — |
| resin | methacrylic acid/methyl | | | | |
| | methacrylate/ethyi acrylate | | | | |
| | (compositional ratio | | | | |
| | (molar ratio) = | | | | |
| | 15/55/30, Mw 60,000, | | | | |
| | acid value 86 mgKOH/g) | | | | |
| | P-4: Copolymer of methacrylic | — | — | — | — |
| | acid/methyl methacrylate/ethyi acrylate | | | | |
| | (compositional ratio (molar ratio) = | | | | |
| | 20/55/25, Mw 60,000, acid value 115 | | | | |
| | mgKOH/g) | | | | |
| | l-19-Ethyl-6-(2-methylbenzyl)-9H- | 0.11 | — | — | — |
| | carbazol-3-yl]ethanone-1- | | | | |
| | (O-acetoxime) | | | | |
| | (OXE-02, manufactured by BASF) | | | | |
| | 1-[4-(Phenylthio)phenyl]octane- | — | 0.11 | — | — |
| | 1,2-dione-2-(O-benzyloxime) | | | | |
| | (OXE01, manufactured by BASF) | | | | |
| | (OXE03, manufactured by BASF) | — | — | 0.11 | — |
| Photopolymerization | 2-(Dimethylamino)-2-(4-methylbenzyl)- | — | — | — | 0.11 |
| initiator | 1-(4-morpholinophenyl)butan-1-one | | | | |
| | (Irgacure 379EG, manufactured by BASF) | | | | |
| | 4-(Dimethylamino)ethyl benzoate | — | 0.21 | 0.21 | 0.21 |
| | (manufactured by DAROCUR EDB, BASF) | | | | |
| | 2-Hydroxy-4′-(2-hydroxyethoxy)-2- | — | — | — | — |
| | methylacetophenone | | | | |
| | (Irgacure 2959, manufactured by BASF) | | | | |
| | 1-(Biphenyl-4-yl)-2-methyl-2- | — | — | — | — |
| | morpholinopropan-1-one | | | | |
| | (Irgacure 307, manufactured by BASF) | | | | |
| | Phenylbis(2,4,6-trimethylbenzyl)phosphine | 0.21 | — | — | — |
| | oxide | | | | |
| | (Irgacure 819, manufactured by BASF) | | | | |
| Blocked | Karenz AOI-BM | — | — | — | — |
| isocyanate | (manufactured by Showa Denko K. K.) | | | | |
| compound | WT32-B75P | 3.62 | 3.62 | 3.62 | 3.62 |
| | (manufactured by Asahi Kasei Corporation) | | | | |
| Additive | N-phenylglycine (manufactured by | 0.03 | 0.03 | 0.03 | 0.03 |
| | Tokyo Chemical Industry Co., Ltd.) | | | | |
| | 1,2,4-Triazole (manufactured by | 0.09 | 0.09 | 0.09 | 0.09 |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | 0.16 | 0.16 | 0.16 | 0.16 |
| | 8032 Additive | | | | |
| | (manufactured by Dow | | | | |
| | Corning Toray Co., Ltd.) | | | | |
| Solvent 1 | 1-Methoxy-2-propyl acetate | 3.46 | 3.46 | 3.46 | 3.46 |
| | Methyl ethyl ketone | 40.00 | 40.00 | 40.00 | 40.00 |

| | | | | |
|---|---|---|---|---|
| Total (parts by mass) | 100 | 100 | 100 | 100 |

TABLE 4

| Raw material | | A-25 | A-26 | A-27 | A-28 |
|---|---|---|---|---|---|
| Polymerizable | Tricyclodecane dimethanol diacrylate | 5.60 | 5.60 | 5.60 | 5.60 |
| compound | (A-DCP, manufactured by | | | | |
| | Shin-Nakamura Chemical Co., Ltd.) | | | | |
| | Monomer with carboxyl group | 0.93 | 0.93 | 0.93 | 0.93 |
| | ARONIX TO-2349 | | | | |
| | (manufactured by Toagosei Co., Ltd.) | | | | |
| | Urethane Acrylate 8UX-015A | — | — | — | — |
| | (manufactured by Taisei Fine | | | | |
| | Chemical Co., Ltd.) | | | | |
| | A-NOD-N | 1.00 | 1.00 | 1.00 | 1.00 |
| | (manufactured by Shin-Nakamura | | | | |
| | Chemical Co., Ltd.) | | | | |
| | A-DPH | 1.80 | 1.80 | 1.80 | 1.80 |
| | (manufactured by Shin-Nakamura | | | | |
| | Chemical Co , Ltd.) | | | | |
| Aliphatic thiol | MTNR1 | — | — | — | — |
| compound | (manufactured by Showa Denko K. K.) | | | | |
| Alkali-soluble | P-1 solution (solid content 36.3% | 42.53 | 42.53 | 42.53 | 42.53 |
| resin | by weight, acid value 95 mgKOH/g, Mw | | | | |
| | 27,000, Mn 15,000) | | | | |
| | P-2 solution (solid content 36.3% | — | — | — | — |
| | by weight, acid value 95 mgKOH/g, Mw | | | | |
| | 17,000, Mn 6.200) | | | | |
| | P-3: Copolymer of methacrylic | — | — | — | — |
| | acid/methyl methacrylate/ethyl acrylate | | | | |
| | (compositional ratio (molar ratio) = | | | | |
| | 15/55/30, Mw 60,000, | | | | |
| | acid value 86 mgKOH/g) | | | | |
| | P-4: Copolymer of methacrylic | — | — | — | — |
| | acid/methyl methacrylate/ethyl acrylate | | | | |
| | (compositional ratio (molar ratio) = | | | | |
| | 20/55/25, Mw 60.000, | | | | |
| | acid value 115 mgKOH/g) | | | | |
| Photopolymenzation | 1-[9-Ethy]-6-(2-methylbenzyl)- | 0.05 | 0.20 | 0.11 | 0.06 |
| initiator | 9H-carbazol-3-yl]ethanone-1-(O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methylbenzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | 0.21 | 0.21 | 0.40 | 0.11 |
| | (manufactured by DAROCUR EDB, BASF) | | | | |
| | 2-Hydroxy-4′-(2-hydroxyethoxy)- | — | — | — | — |
| | 2-methylacetophenone | | | | |
| | (Irgacure 2959, manufactured by BASF) | | | | |
| | 1-(Biphenyl-4-yl)-2-methyl-2- | — | — | — | — |
| | morpholinopropan-1-one | | | | |
| | (Irgacure 307, manufactured by BASF) | | | | |
| | Phenylbis(2,4,6-trimethylbenzyl)phosphine | — | — | — | — |
| | oxide (Irgacure 819, manufactured by BASF) | | | | |
| Blocked isocyanate | Karenz AOI-BM | — | — | — | — |
| compound | (manufactured by Showa Denko K. K.) | | | | |
| | WT32-B75P | 3.62 | 3.62 | 3.62 | 3.62 |
| | (manufactured by Asahi Kasei Corporation) | | | | |
| Additive | N-phenylglycine (manufactured by | 0.03 | 0.03 | 0.03 | 0.03 |
| | Tokyo Chemical Industry Co., Ltd.) | | | | |
| | 1,2,4-Triazole (manufactured by | 0.09 | 0.09 | 0.09 | 0.09 |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.03 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 80.32 Additive (manufactured by | | | | |
| | Dow Corning Toray Co., Ltd.) | | | | |
| Solvent 1 | 1-Methoxy-2-propyl acetate | 3.68 | 3.53 | 3.43 | 3.77 |
| | Methyl ethyl ketone | 40.00 | 40.00 | 40.00 | 40.00 |
| Total (parts by mass) | | 100 | 100 | 100 | 100 |
| Raw material | | A-29 | A-30 | A-31 | A-32 |
| Polymerizable | Tricyclodecane dimethanol diacrylate | — | 4.93 | 6.16 | 5.60 |
| compound | (A-DCP, manufactured by | | | | |
| | Shin-Nakamura Chemical Co., Ltd.) | | | | |
| | Monomer with carboxyl group | — | 0.82 | 1.02 | 0.93 |
| | ARONIX TO-2349 | | | | |
| | (manufactured by Toagosei Co., Ltd.) | | | | |
| | Urethane Acrylate 8UX-015A | — | — | — | — |
| | (manufactured by Taisei Fine | | | | |
| | Chemical Co., Ltd.) | | | | |
| | A-NOD-N | 5.60 | 0.88 | 1.10 | 1.00 |
| | (manufactured by Shin-Nakamura | | | | |
| | Chemical Co., Ltd.) | | | | |
| | A-DPH | 3.7.3 | 1.58 | 1.98 | 1.80 |
| | (manufactured by Shin-Nakamura | | | | |
| | Chemical Co , Ltd.) | | | | |
| Aliphatic thiol | MTNR1 | — | — | — | — |
| compound | (manufactured by Showa Denko K. K.) | | | | |
| Alkali-soluble | P-1 solution (solid content 36.3% | 42.53 | 45.62 | 39.97 | 42.53 |
| resin | by weight, acid value 95 mgKOH/g, Mw | | | | |
| | 27,000, Mn 15,000) | | | | |
| | P-2 solution (solid content 36.3% | — | — | — | — |
| | by weight, acid value 95 mgKOH/g, Mw | | | | |
| | 17,000, Mn 6.200) | | | | |
| | P-3: Copolymer of methacrylic | — | — | — | — |
| | acid/methyl methacrylate/ethyl acrylate | | | | |
| | (compositional ratio (molar ratio) = | | | | |
| | 15/55/30, Mw 60,000, | | | | |
| | acid value 86 mgKOH/g) | | | | |
| | P-4: Copolymer of methacrylic | — | — | — | — |
| | acid/methyl methacrylate/ethyl acrylate | | | | |
| | (compositional ratio (molar ratio) = | | | | |
| | 20/55/25, Mw 60.000, | | | | |
| | acid value 115 mgKOH/g) | | | | |
| Photopolymenzation | 1-[9-Ethy]-6-(2-methylbenzyl)- | 0.20 | 0.11 | 0.11 | 0.11 |
| initiator | 9H-carbazol-3-yl]ethanone-1-(O-acetoxime) | | | | |
| | (OXE-02, manufactured by BASF) | | | | |
| | 1-[4-(Phenylthio)phenyl]octane- | — | — | — | — |
| | 1,2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methylbenzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | 0.30 | 0.21 | 0.21 | 0.21 |
| | (manufactured by DAROCUR EDB, BASF) | | | | |
| | 2-Hydroxy-4′-(2-hydroxyethoxy)- | — | — | — | — |
| | 2-methylacetophenone | | | | |
| | (Irgacure 2959, manufactured by BASF) | | | | |
| | 1-(Biphenyl-4-yl)-2-methyl-2- | — | — | — | — |
| | morpholinopropan-1-one | | | | |
| | (Irgacure 307, manufactured by BASF) | | | | |
| | Phenylbis(2,4,6-trimethylbenzyl)phosphine | — | — | — | — |
| | oxide (Irgacure 819, manufactured by BASF) | | | | |
| Blocked isocyanate | Karenz AOI-BM | — | — | — | — |
| compound | (manufactured by Showa Denko K. K.) | | | | |
| | WT32-B75P | 3.62 | 3.62 | 3.62 | — |
| | (manufactured by Asahi Kasei Corporation) | | | | |
| Additive | N-phenylglycine (manufactured by | 0.03 | 0.03 | 0.03 | 0.03 |
| | Tokyo Chemical Industry Co., Ltd.) | | | | |
| | 1,2,4-Triazole (manufactured by | 0.09 | 0.09 | 0.09 | — |
| | Otsuka Chemical Co., Ltd.) | | | | |
| | Benzimidazole (manufactured by | — | — | — | — |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | — | — | — | — |
| | Tokyo Chemical Industry Co., Ltd.) | | | | |
| | SMA EF-40 (manufactured by | 0.30 | 0.30 | 0.30 | — |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 80.32 Additive (manufactured by | | | | |
| | Dow Corning Toray Co., Ltd.) | | | | |
| Solvent 1 | 1-Methoxy-2-propyl acetate | 3.44 | 1.65 | 5.25 | 7.63 |
| | Methyl ethyl ketone | 40.00 | 40.00 | 40.00 | 40.00 |

| | | | | |
|---|---|---|---|---|
| Total (parts by mass) | 100 | 100 | 100 | 100 |

TABLE 5

| Raw material | | A′-1 | A′-2 | A′-3 | A′-4 |
|---|---|---|---|---|---|
| Polymerizable | Tricyclodecane dimethanol diacrylate | 5.60 | 5.60 | 5.60 | 5.60 |
| compound | (A-DCP, manufactured by Shin-Nakamura Chemical Co., Ltd.) | | | | |
| | Monomer with carboxyl group ARONIX TO-2349 | 0.93 | 0.93 | 0.93 | 0.93 |
| | (manufactured by Toagosei Co., Ltd.) | | | | |
| | Urethane Acrylate 8UX-015A | — | — | — | — |
| | (manufactured by Taisei Fine Chemical Co., Ltd.) | | | | |
| | A-NOD-N | 1.00 | 1.00 | 1.00 | 1.00 |
| | (manufactured by Shin-Nakamura Chemical Co., Ltd.) | | | | |
| | A-DPH | 1.80 | 1.80 | 1.80 | 1.80 |
| | (manufactured by Shin-Nakamura Chemical Co., Ltd.) | | | | |
| Aliphatic thiol | MTNR1 | — | — | — | — |
| compound | (manufactured by Showa Denko K. K.) | | | | |
| Alkali-soluble resin | P-1 solution (solid content 36.3% by weight, acid value 95 mgKOH/g, Mw | — | — | — | |
| | 27,000, Mn 15,000) | | | | |
| | P-2 solution (solid content 36.3% by weight, acid value 95 mgKOH/g, Mw | 42.53 | 42.53 | 42.53 | 42.53 |
| | 17,000, Mn 6,200) | | | | |
| | P-3: Copolymer of methacrylic acid/methyl methacrylate/ethyl acrylate | — | — | — | — |
| | (compositional ratio (molar ratio) = 15/55/30, Mw 60,000, acid value 86 | | | | |
| | mgKOH/g) | | | | |
| | P-4: Copolymer of methacrylic acid/methyl methacrylate/ethyl acrylate | — | — | — | — |
| | (compositional ratio (molar ratio) - 20/55/25, Mw 60,000, acid value 115 | | | | |
| | mgKOH/g) | | | | |
| | P-5 solution (solid content 36.2% by weight, acid value 124 mgKOH/g, Mw | — | — | — | — |
| | 18,000, Mn 7,800) | | | | |
| | P-5 solution (solid content 36.2% by weight, acid value 124 mgKOH/g, Mw | — | — | — | — |
| | 18,000, Mn 7,800) | | | | |
| Photopolymerization | 1-[9-Ethyl-6-(2-methylbenzyl)-9H-carbazol-3-yl]ethanone-l-(O-acetoxime) | 0.11 | 0.50 | 0.06 | - |
| initiator | (OχE-02, manufactured by BASF) | | | | |
| | 1-[4-(Phenylthio)phenyl]octane-1,2-dione-2-(O-benzyloxime) | — | — | 0.06 | — |
| | (OXE01, manufactured by BASF) | | | | |
| | (OXE03, manufactured by BASF) | — | — | — | — |
| | 2-(Dimethylamino)-2-(4-methylbenzyl)-1-(4-morpholinophenyi)butan-l-one | — | — | — | — |
| | (Irgacure 379EG, manufactured by BASF) | | | | |
| | 4-(Dimethylamino)ethyl benzoate | — | — | — | — |
| | (manufactured by DAROCUR EDB, BASF) | | | | |
| | 2-Hydroxy-4′-(2-hydroxyethoxy)-2-methylaeetophenone | — | — | — | — |
| | (Irgacure 2959, manufactured by BASF) | | | | |
| | 1-(Biphenyl-4-yl)-2-methyl-2-morphoiinopropan-1-one | — | — | — | — |
| | (Irgacure 307, manufactured by BASF) | | | | |
| | 1-(Biphenyl-4-yl)-2-methyl-2-morpholinopropan-1-one | — | — | — | 1.85 |
| | (APi 307, manufactured by Shenzhen UV-ChemTech Ltd.) | | | | |
| Photopolymerization | Phenylbis(2,4,6-trimethylbenzyl)phosphine oxide | — | — | — | — |
| initiator | (Irgacure 819, manufactured by BASF) | | | | |
| | 2,4,6-Trimethylbenzyl-diphenylphosphine oxide | — | — | — | 0.11 |
| | (Irgacure TPO, manufactured by BASF) | | | | |
| Blocked Isocyanate | Karenz AOI-BM (manufactured by Showa Denko K. K.) | — | — | — | — |
| Compound | WT32-B75P (manufactured by Asahi Kasei Corporation) | 3.62 | 3.62 | 3.62 | 3.62 |
| | X6010-4 (manufactured by Asahi Kasei Corporation) | — | — | — | — |
| | The following compound B | — | — | — | — |
| | The following compound C | — | — | — | — |
| Additive | N-Phenylglycine (manufactured by Tokyo Chemical industry Co., Ltd.) | — | — | — | — |
| | 1,2,4-Triazole (manufactured by Otsuka Chemical Co., Ltd.) | 0.09 | 0.09 | 0.09 | 0.09 |
| | Benzimidazole (manufactured by Tokyo Chemical Industry Co., Ltd.) | — | — | — | — |
| | 5-Amino-1H-tetrazole (manufactured by Tokyo Chemical Industry Co., Ltd.) | — | — | — | — |
| | Isonicotinamide (manufactured by Tokyo Chemical Industry Co., Ltd.) | — | — | — | — |
| | SMA EF-40 (manufactured by Tomoegawa Co., Ltd) | 0.30 | 0.30 | 0.30 | 0.30 |
| | MEGAFACE F551A (manufactured by DIC Corporation) | 0.16 | 0 16 | 0.16 | 0.16 |
| | DOWSIL (registered trademark) 8032 Additive (manufactured by Dow | 0.16 | 0.16 | 0.16 | 0.16 |
| | Corning Toray Co., Ltd.) | | | | |
| | Ftergent 710F (manufactured by Neos Corporation) | — | — | — | — |
| | MEGAFACE R-41 (manufactured by DIC Corporation) | — | — | — | — |
| | MEGAFACE F-563 (manufactured by DIC Corporation) | — | — | — | — |
| Solvent | 1-Methoxy-2-propyl acetate | 3.70 | 3.31 | 3.69 | 1.85 |
| | Methyl ethyl ketone | 40.00 | 40.00 | 40.00 | 40.00 |

| | | | | |
|---|---|---|---|---|
| Total (parts by mass) | 100 | 100 | 100 | 100 |

TABLE 6

| Raw material | | A-33 | A-34 | A-35 | A-36 |
|---|---|---|---|---|---|
| Polymerizable | Tricyclodecane dimethanol diacrylate | 2.28 | 2.28 | 2.46 | 2.46 |
| compound | (A-DCP, manufactured by | | | | |
| | Shin-Nakamura Chemical Co., Ltd.) | | | | |
| | Monomer with carboxyl group | 0.95 | 0.95 | 1.03 | 1.03 |
| | ARONIX TO-2349 | | | | |
| | (manufactured by | | | | |
| | Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N | 0.70 | 0.70 | 0.75 | 0.75 |
| | (manufactured by Shin-Nakamura | | | | |
| | Chemical Co., Ltd.) | | | | |
| | A-DPH | 4.32 | 4.32 | 4.66 | 4.66 |
| | (manufactured by Shin-Nakamura | | | | |
| | Chemical Co., Ltd.) | | | | |
| Aliphatic thiol | MTNR1 | — | — | — | — |
| compound | (manufactured by Showa Denko | | | | |
| | K. K.) | | | | |
| Alkali-soluble | P-1 solution (solid content | — | — | — | — |
| resin | 36.3% by weight, acid value | | | | |
| | 95 mgKOH/g, Mw 27,000, | | | | |
| | Mn 15,000) | | | | |
| | P-2 solution (solid content | — | — | — | — |
| | 36.3% by weight, acid value | | | | |
| | 95 mgKOH/g, Mw 17,000, | | | | |
| | Mn 6,200) | | | | |
| | P-3 Copolymer of methacrylic | — | — | — | — |
| | acid/methyl methacrylate/ethyl acrylate | | | | |
| | (compositional ratio (molar | | | | |
| | ratio) = 15/55/30, | | | | |
| | Mw 60,000, acid value 86 mgKOH/g) | | | | |
| | P-4: Copolymer of methacrylic | — | — | — | — |
| | acid/methyl methacrylate/ethyl | | | | |
| | acrylate | | | | |
| | (compositional ratio (molar | | | | |
| | ratio) 20/55/25, Mw 60,000, | | | | |
| | acid value 115 mgKOH/g) | | | | |
| | P-5 solution (solid content | 33.77 | 33.77 | 32.00 | 32.00 |
| | 36.2% by weight, | | | | |
| | acid value 124 mgKOH/g, | | | | |
| | Mw 18,000, Mn 7,800) | | | | |
| | P-6 solution (solid content | — | — | — | — |
| | 36.2% by weight, acid value | | | | |
| | 114 mgKOH/g, Mw 18,000, Mn 7,800) | | | | |
| Photopolymerization | 1-[9-Ethyl-6-(2-methylbenzyl)- | 0.09 | 0.09 | 0.10 | 0.10 |
| initiator | 9H-carbazol-3-yl]ethanone-1- | | | | |
| | (O-acetoxime) | | | | |
| | (OXF-02, manufactured by BASF) | | | | |
| | 1-[4-(Phenylthio)phenyl]octane-1, | — | — | — | — |
| | 2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methylbenzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | — | — | — | — |
| | (manufactured by DAROCUR EDB, BASF) | | | | |
| | 2-Hydroxy-4′-(2-hydroxyethoxy)-2- | — | — | — | — |
| | methylacetophenone | | | | |
| | (Irgacure 2959, manufactured by BASF) | | | | |
| Photopolymerization | 1-(Biphenyl-4-yl)-2-methyl-2- | — | — | — | — |
| initiator | morpholinopropan-1-one | | | | |
| | (Irgacure 307, manufactured by BASF) | | | | |
| | 1-(Biphenyl-4-yl)-2-methyl-2- | 1.85 | 1.85 | 2.00 | 2.00 |
| | morpholinopropan-1-one | | | | |
| | (APi 307, manufactured by Shenzhen | | | | |
| | UV-ChemTech Ltd.) | | | | |
| | Phenylbis(2,4,6-trimethylbenzyl) | — | — | — | — |
| | phosphine oxide | | | | |
| | (Irgacure 819, manufactured by BASF) | | | | |
| | 2,4,6-Trimethylbenzyl-diphenylphosphine | — | — | — | — |
| | oxide | | | | |
| | (Irgacure TPO, manufactured by BASF) | | | | |
| Blocked Isocyanate | Karenz AOI-BM (manufactured | — | — | — | — |
| Compound | by Showa Denko K. K.) | | | | |
| | WT32-B75P (manufactured by | 4.46 | — | 4.46 | — |
| | Asahi Kasei Corporation) | | | | |
| | X6010-4 (manufactured by | — | 4.46 | — | 4.46 |
| | Asahi Kasei Corporation) | | | | |
| | The following compound B | 0.74 | 0.74 | 0.74 | 0.54 |
| | The following compound C | — | — | — | — |
| Additive | N-Phenylglycine (manufactured by | 0.03 | 0.03 | 0.03 | 0.03 |
| | Tokyo Chemical Industry Co., Ltd.) | | | | |
| | 1,2,4-Triazole (manufactured by | — | — | — | — |
| | Otsuka Chemical Co., Ltd.) | | | | |
| | Benzimidazole (manufactured by | 0.03 | 0.03 | 0.03 | 0.03 |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | 0.01 | 0.01 | 0.01 | 0.01 |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 8032 Additive (manufactured by | | | | |
| | Dow Corning Toray Co., Ltd.) | | | | |
| | Ftergent 710F (manufactured by | — | — | — | — |
| | Neos Corporation) | | | | |
| | MEGAFACE R-41 (manufactured by | — | — | — | — |
| | DIC Corporation) | | | | |
| | MEGAFACE F-563 (manufactured by | — | — | — | — |
| | DIC Corporation) | | | | |
| Solvent | 1-Methoxy-2-propyl acetate | 7.71 | 7.71 | 8.67 | 8.67 |
| | Methyl ethyl ketone | 42.60 | 42.60 | 42.60 | 42.60 |
| Total (parts by mass) | | 100 | 100 | 100 | 100 |
| Raw material | | A-37 | A-38 | A-39 | A-40 |
| Polymerizable | Tricyclodecane dimethanol diacrylate | 2.05 | 2.28 | 2.28 | 2.28 |
| compound | (A-DCP, manufactured by | | | | |
| | Shin-Nakamura Chemical Co., Ltd.) | | | | |
| | Monomer with carboxyl group | 0.85 | 0.95 | 0.95 | 0.95 |
| | ARONIX TO-2349 | | | | |
| | (manufactured by | | | | |
| | Toagosei Co., Ltd.) | | | | |
| | Urethane Acrylate 8UX-015A | — | — | — | — |
| | (manufactured by | | | | |
| | Taisei Fine Chemical Co., Ltd.) | | | | |
| | A-NOD-N | 0.62 | 0.70 | 0.70 | 0.70 |
| | (manufactured by Shin-Nakamura | | | | |
| | Chemical Co., Ltd.) | | | | |
| | A-DPH | 3.87 | 4.32 | 4.32 | 4.32 |
| | (manufactured by Shin-Nakamura | | | | |
| | Chemical Co., Ltd.) | | | | |
| Aliphatic thiol | MTNR1 | — | — | — | — |
| compound | (manufactured by Showa Denko | | | | |
| | K. K.) | | | | |
| Alkali-soluble | P-1 solution (solid content | — | — | — | — |
| resin | 36.3% by weight, acid value | | | | |
| | 95 mgKOH/g, Mw 27,000, | | | | |
| | Mn 15,000) | | | | |
| | P-2 solution (solid content | — | — | — | — |
| | 36.3% by weight, acid value | | | | |
| | 95 mgKOH/g, Mw 17,000, | | | | |
| | Mn 6,200) | | | | |
| | P-3 Copolymer of methacrylic | — | — | — | — |
| | acid/methyl methacrylate/ethyl acrylate | | | | |
| | (compositional ratio (molar | | | | |
| | ratio) = 15/55/30, | | | | |
| | Mw 60,000, acid value 86 mgKOH/g) | | | | |
| | P-4: Copolymer of methacrylic | — | — | — | — |
| | acid/methyl methacrylate/ethyl | | | | |
| | acrylate | | | | |
| | (compositional ratio (molar | | | | |
| | ratio) 20/55/25, Mw 60,000, | | | | |
| | acid value 115 mgKOH/g) | | | | |
| | P-5 solution (solid content | 36.17 | — | — | 33.77 |
| | 36.2% by weight, | | | | |
| | acid value 124 mgKOH/g, | | | | |
| | Mw 18,000, Mn 7,800) | | | | |
| | P-6 solution (solid content | — | 33.77 | 33.77 | — |
| | 36.2% by weight, acid value | | | | |
| | 114 mgKOH/g, Mw 18,000, Mn 7,800) | | | | |
| Photopolymerization | 1-[9-Ethyl-6-(2-methylbenzyl)- | 0.08 | 0.09 | 0.09 | 0.09 |
| initiator | 9H-carbazol-3-yl]ethanone-1- | | | | |
| | (O-acetoxime) | | | | |
| | (OXE-02, manufactured by BASF) | | | | |
| | 1-[4-(Phenylthio)phenyl]octane-1, | — | — | — | — |
| | 2-dione-2-(O-benzyloxime) | | | | |
| | (OXE01, manufactured by BASF) | | | | |
| | (OXE03, manufactured by BASF) | — | — | — | — |
| | 2-(Dimethylamino)-2-(4-methylbenzyl)- | — | — | — | — |
| | 1-(4-morpholinophenyl)butan-1-one | | | | |
| | (Irgacure 379EG, manufactured by BASF) | | | | |
| | 4-(Dimethylamino)ethyl benzoate | — | — | — | — |
| | (manufactured by DAROCUR EDB, BASF) | | | | |
| | 2-Hydroxy-4′-(2-hydroxyethoxy)-2- | — | — | — | — |
| | methylacetophenone | | | | |
| | (Irgacure 2959, manufactured by BASF) | | | | |
| Photopolymerization | 1-(Biphenyl-4-yl)-2-methyl-2- | — | — | — | — |
| initiator | morpholinopropan-1-one | | | | |
| | (Irgacure 307, manufactured by BASF) | | | | |
| | 1-(Biphenyl-4-yl)-2-methyl-2- | 1.66 | 1.85 | 1.85 | 1.85 |
| | morpholinopropan-1-one | | | | |
| | (APi 307, manufactured by Shenzhen | | | | |
| | UV-ChemTech Ltd.) | | | | |
| | Phenylbis(2,4,6-trimethylbenzyl) | — | — | — | — |
| | phosphine oxide | | | | |
| | (Irgacure 819, manufactured by BASF) | | | | |
| | 2,4,6-Trimethylbenzyl-diphenylphosphine | — | — | — | — |
| | oxide | | | | |
| | (Irgacure TPO, manufactured by BASF) | | | | |
| Blocked Isocyanate | Karenz AOI-BM (manufactured | — | — | — | — |
| Compound | by Showa Denko K. K.) | | | | |
| | WT32-B75P (manufactured by | — | 4.46 | — | — |
| | Asahi Kasei Corporation) | | | | |
| | X6010-4 (manufactured by | 4.46 | — | 4.46 | 4.46 |
| | Asahi Kasei Corporation) | | | | |
| | The following compound B | 0.54 | 0.54 | 0.74 | — |
| | The following compound C | — | — | — | 0.54 |
| Additive | N-Phenylglycine (manufactured by | 0.03 | 0.03 | 0.03 | 0.03 |
| | Tokyo Chemical Industry Co., Ltd.) | | | | |
| | 1,2,4-Triazole (manufactured by | — | — | — | — |
| | Otsuka Chemical Co., Ltd.) | | | | |
| | Benzimidazole (manufactured by | 0.03 | 0.03 | 0.03 | 0.03 |
| | Tokyo Chemical Industry Co., Ltd.) | | | | |
| | 5-Amino-1H-tetrazole (manufactured by | — | — | — | — |
| | Tokyo Chemical Industry Co., Ltd.) | | | | |
| | Isonicotinamide (manufactured by | 0.01 | 0.01 | 0.01 | 0.01 |
| | Tokyo Chemical Industry Co., Ltd.) | | | | |
| | SMA EF-40 (manufactured by | 0.30 | 0.30 | 0.30 | 0.30 |
| | Tomoegawa Co., Ltd.) | | | | |
| | MEGAFACE F551A (manufactured by | 0.16 | 0.16 | 0.16 | 0.16 |
| | DIC Corporation) | | | | |
| | DOWSIL (registered trademark) | — | — | — | — |
| | 8032 Additive (manufactured by | | | | |
| | Dow Corning Toray Co., Ltd.) | | | | |
| | Ftergent 710F (manufactured by | — | — | — | — |
| | Neos Corporation) | | | | |
| | MEGAFACE R-41 (manufactured by | — | — | — | — |
| | DIC Corporation) | | | | |
| | MEGAFACE F-563 (manufactured by | — | — | — | — |
| | DIC Corporation) | | | | |
| Solvent | 1-Methoxy-2-propyl acetate | 6.37 | 7.71 | 7.71 | 7.71 |
| | Methyl ethyl ketone | 42.60 | 42.60 | 42.60 | 42.60 |

| | | | | |
|---|---|---|---|---|
| Total (parts by mass) | 100 | 100 | 100 | 100 |

TABLE 7

| Raw material | | A-41 | A-42 | A-43 | A-44 | A-45 | A-46 |
|---|---|---|---|---|---|---|---|
| Polymerizable | Tricyclodecane dimethanol | 2.28 | 4.84 | — | 2.28 | 2.28 | 2.28 |
| compound | diacrylate | | | | | | |
| | (A-DCP, manufactured by | | | | | | |
| | Shin-Nakamura Chemical Co., Ltd.) | | | | | | |
| | Monomer with carboxyl | 0.95 | 0.95 | 0.95 | 0.95 | 0.95 | 0.95 |
| | group ARONIX 10-2349 | | | | | | |
| | (manufactured by | | | | | | |
| | Toagosei Co., Ltd.) | | | | | | |
| | Urethane Acrylate 8UX-015A | — | — | — | — | — | — |
| | (manufactured by Taisei | | | | | | |
| | Fine Chemical Co., Ltd.) | | | | | | |
| | A-NOD-N | 0.70 | 0.81 | 2.98 | 0.70 | 0.70 | 0.70 |
| | (manufactured by Shin-Nakamura | | | | | | |
| | Chemical Co., Ltd.) | | | | | | |
| | A-DPH | 4.32 | 1.66 | 4.32 | 4.32 | 4.32 | 4.32 |
| | (manufactured by Shin-Nakamura | | | | | | |
| | Chemical Co., Ltd.) | | | | | | |
| Aliphatic | MTNR1 | — | — | — | — | — | — |
| thiol | (manufactured by | | | | | | |
| compound | Showa Denko K. K.) | | | | | | |
| Alkali- | P-1 solution (solid content | — | — | — | — | — | — |
| soluble | 36.3% by weight, | | | | | | |
| resin | acid value 95 mgKOH/g, Mw | | | | | | |
| | 27,000, Mn 15,000) | | | | | | |
| | P-2 solution (solid content | — | — | — | — | — | — |
| | 36.3% by weight, | | | | | | |
| | acid value 95 mgKOH/g, Mw | | | | | | |
| | 17,000, Mn 6,200) | | | | | | |
| | P-3: Copolymer of methacrylic | — | — | — | — | — | — |
| | acid/methyl methacrylate/ethyl | | | | | | |
| | acrylate | | | | | | |
| | (compositional ratio | | | | | | |
| | (molar ratio) = 15/55/30, | | | | | | |
| | Mw 60,000, | | | | | | |
| | acid value 86 mgKOH/g) | | | | | | |
| | P-4: Copolymer of | — | — | — | — | — | — |
| | methacrylic acid/methyl | | | | | | |
| | methacrylate/ethyl acrylate | | | | | | |
| | (compositional ratio | | | | | | |
| | (molar ratio) = 20/55/25, | | | | | | |
| | Mw 60,000, | | | | | | |
| | acid value 115 mgKOH/g) | | | | | | |
| | P-5 solution (solid content | 33.77 | 33.77 | 33.77 | 33.77 | 33.77 | 33.77 |
| | 36.2% by weight, acid value | | | | | | |
| | 124 mgKOH/g, Mw | | | | | | |
| | 18,000. Mn 7,800) | | | | | | |
| | P-6 solution (solid content | — | — | — | — | — | — |
| | 36.2% by weight, acid value | | | | | | |
| | 114 mgKOH/g, Mw | | | | | | |
| | 18,000, Mn 7,800) | | | | | | |
| Photopolymerization | 1-[9-Ethyl-6-(2-methylbenzyl)- | 0.09 | 0.09 | 0.09 | 0.30 | 0.08 | 0.09 |
| initiator | 9H-carbazol-3-yl]ethanone-1- | | | | | | |
| | (O-acetoxime) | | | | | | |
| | (OXE-02, manufactured by BASF) | | | | | | |
| | 1-[4-(Phenylthio)phenyl]octane- | — | — | — | — | — | — |
| | 1,2-dione-2-(O-benzyloxime) | | | | | | |
| | (OXE01, manufactured by BASF) | | | | | | |
| | (OXE03, manufactured by BASF) | — | — | — | — | — | — |
| | 2-(Dimethylamino)-2-(4-methylbenzyl)-1- | — | — | — | — | — | — |
| | (4-morpholinophenyl)butan-1-one | | | | | | |
| | (Irgacure 379EG, manufactured by BASF) | | | | | | |
| | 4-(Dimethylamino)ethyl benzoate | — | — | — | — | — | — |
| | (manufactured by | | | | | | |
| | DAROCUR EDB, BASF) | | | | | | |
| | 2-Hydroxy-4′-(2-hydroxyerhoxy)-2- | — | — | — | — | — | 5.00 |
| | methylacetophenone | | | | | | |
| | (Irgacure 2959, manufactured by BASF) | | | | | | |
| | 1-(Biphenyl-4-yl)-2-methy1-2- | 1.85 | — | — | — | — | — |
| | morpholinopropan-1-one | | | | | | |
| | (Irgacure 307, manufactured by BASF) | | | | | | |
| | 1-(Biphenyl-4-yl)-2-methy1-2- | — | 1.85 | 1.85 | 1.85 | 3.00 | — |
| | morpholinopropan-1-one | | | | | | |
| | (APi 307, manufactured by | | | | | | |
| | Shenzhen UV-ChemTech Ltd.) | | | | | | |
| | Phenylbis(2,4,6-trimethylbenzyl) | — | — | — | — | — | — |
| | phosphine oxide (Irgacure 819, | | | | | | |
| | manufactured by BASF) | | | | | | |
| | 2,4,6-Trimethylbenzyl- | — | — | — | — | — | — |
| | diphenylphosphine | | | | | | |
| | oxide (Irgacure TPO, | | | | | | |
| | manufactured by BASF) | | | | | | |
| Blocked isocyanate | Karenz AOI-BM (manufactured by | 4.46 | — | — | — | — | — |
| Compound | Showa Denko K. K.) | | | | | | |
| | WT32-B75P (manufactured by | — | — | — | — | — | — |
| | Asahi Kasei Corporation) | | | | | | |
| | X6010-4 (manufactured by | — | 4.46 | 4.46 | 4.46 | 4.46 | 4 46 |
| | Asahi Kasei Corporation) | | | | | | |
| | The following compound B | — | 0.74 | 0.74 | 0.74 | 0.74 | 0.74 |
| | The following compound C | — | — | — | — | — | — |
| Additive | N-Phenylglycine (manufactured by | 0.03 | 0.03 | 0.03 | 0.03 | 0.03 | 0.03 |
| | Tokyo Chemical Industry Co., Ltd.) | | | | | | |
| | 1,2,4-Triazole (manufactured by | — | — | — | — | — | — |
| | Otsuka Chemical Co., Ltd.) | | | | | | |
| | Benzimidazole (manufactured by | 0.03 | 0.03 | 0.03 | 0.03 | 0.03 | 0.0.3 |
| | Tokyo Chemical Industry Co., Ltd.) | | | | | | |
| | 5-Amino-1H-tetrazole (manufactured by | — | — | — | — | — | — |
| | Tokyo Chemical Industry Co., Ltd.) | | | | | | |
| | Isomicotinamide (manufactured by | 0.01 | 0.01 | 0.01 | 0.01 | 0.01 | 0.01 |
| | Tokyo Chemical Industry Co., Ltd.) | | | | | | |
| | SMA EF-40 (manufactured by | 0.30 | 0.30 | 0.30 | 0.30 | 0.30 | 0.30 |
| | Tomoegawa Co., Ltd.) | | | | | | |
| | MEGAFACE F551A (manufactured by | 0.16 | 0.16 | 0.16 | 0.16 | 0.16 | 0.16 |
| | DIC Corporation) | | | | | | |
| | DOWSIL (registered trademark) | — | — | — | — | — | — |
| | 8032 Additive (manufactured by Dow | | | | | | |
| | Corning Toray Co., Ltd.) | | | | | | |
| | Ftergent 710F (manufactured by | — | — | — | — | — | — |
| | Neos Corporation) | | | | | | |
| | MEGAFACE R-41 (manufactured by | — | — | — | — | — | — |
| | DIC Corporation) | | | | | | |
| | MEGAFACE F-563 (manufactured by | — | — | — | — | — | — |
| | DIC Corporation) | | | | | | |
| Solvent | 1-Methoxy-2-propyl acetate | 8.45 | 7.70 | 7.71 | 7.50 | 6.57 | 4.56 |
| | Methyl ethyl ketone | 42.60 | 42.60 | 42.60 | 42.60 | 42.60 | 42.60 |
| Total (parts by mass) | | 100 | 100 | 100 | 100 | 100 | 100 |
| Raw material | | A-47 | A-48 | A-49 | A-50 | A-51 | A-52 |
| Polymerizable | Tricyclodecane dimethanol | 2.28 | 2.28 | 2.28 | 2.28 | 2.28 | 2.28 |
| compound | diacrylate | | | | | | |
| | (A-DCP, manufactured by | | | | | | |
| | Shin-Nakamura Chemical Co., Ltd.) | | | | | | |
| | Monomer with carboxyl | 0.95 | 0.95 | 0.95 | 0.95 | 0.95 | 0.95 |
| | group ARONIX 10-2349 | | | | | | |
| | (manufactured by | | | | | | |
| | Toagosei Co., Ltd.) | | | | | | |
| | Urethane Acrylate 8UX-015A | — | — | — | — | — | — |
| | (manufactured by Taisei | | | | | | |
| | Fine Chemical Co., Ltd.) | | | | | | |
| | A-NOD-N | 0.70 | 0.70 | 0.70 | 0.70 | 0.70 | 0.70 |
| | (manufactured by Shin-Nakamura | | | | | | |
| | Chemical Co., Ltd.) | | | | | | |
| | A-DPH | 4.32 | 4.32 | 4.32 | 4.32 | 4.32 | 4.32 |
| | (manufactured by Shin-Nakamura | | | | | | |
| | Chemical Co., Ltd.) | | | | | | |
| Aliphatic | MTNR1 | — | — | — | — | — | — |
| thiol | (manufactured by | | | | | | |
| compound | Showa Denko K. K.) | | | | | | |
| Alkali- | P-1 solution (solid content | — | — | — | — | — | — |
| soluble | 36.3% by weight, | | | | | | |
| resin | acid value 95 mgKOH/g, Mw | | | | | | |
| | 27,000, Mn 15,000) | | | | | | |
| | P-2 solution (solid content | — | — | — | — | — | — |
| | 36.3% by weight, | | | | | | |
| | acid value 95 mgKOH/g, Mw | | | | | | |
| | 17,000, Mn 6,200) | | | | | | |
| | P-3: Copolymer of methacrylic | — | — | — | — | — | — |
| | acid/methyl methacrylate/ethyl | | | | | | |
| | acrylate | | | | | | |
| | (compositional ratio | | | | | | |
| | (molar ratio) = 15/55/30, | | | | | | |
| | Mw 60,000, | | | | | | |
| | acid value 86 mgKOH/g) | | | | | | |
| | P-4: Copolymer of | — | — | — | — | — | — |
| | methacrylic acid/methyl | | | | | | |
| | methacrylate/ethyl acrylate | | | | | | |
| | (compositional ratio | | | | | | |
| | (molar ratio) = 20/55/25, | | | | | | |
| | Mw 60,000, | | | | | | |
| | acid value 115 mgKOH/g) | | | | | | |
| | P-5 solution (solid content | 33.77 | 33.77 | 33.77 | 33.77 | 33.77 | 33.77 |
| | 36.2% by weight, acid value | | | | | | |
| | 124 mgKOH/g, Mw | | | | | | |
| | 18,000, Mn 7,800) | | | | | | |
| | P-6 solution (solid content | — | — | — | — | — | — |
| | 36.2% by weight, acid value | | | | | | |
| | 114 mgKOH/g, Mw | | | | | | |
| | 18,000, Mn 7,800) | | | | | | |
| Photopolymerization | 1-[9-Ethyl-6-(2-methylbenzyl)- | — | — | 0.09 | 0.09 | — | 0.09 |
| initiator | 9H-carbazol-3-yl]ethanone-1- | | | | | | |
| | (O-acetoxime) | | | | | | |
| | (OXE-02, manufactured by BASF) | | | | | | |
| | 1-[4-(Phenylthio)phenyl]octane- | — | — | — | — | — | — |
| | 1,2-dione-2-(O-benzyloxime) | | | | | | |
| | (OXE01, manufactured by BASF) | | | | | | |
| | (OXE03, manufactured. by BASF) | — | — | — | — | — | — |
| | 2-(Dimethylamino)-2-(4-methylbenzyl)-1- | 0.20 | 0.20 | — | — | — | — |
| | (4-morpholinophenyl)butan-1-one | | | | | | |
| | (Irgacure 379EG, manufactured by BASF) | | | | | | |
| | 4-(Dimethylamino)ethyl benzoate | — | — | — | — | — | — |
| | (manufactured by | | | | | | |
| | DAROCUR EDB, BASF) | | | | | | |
| | 2-Hydroxy-4′-(2-hydroxyerhoxy)-2- | — | 5.00 | — | — | — | — |
| | methylacetophenone | | | | | | |
| | (Irgacure 2959, manufactured by BASF) | | | | | | |
| | 1-(Biphenyl-4-yl)-2-methy1-2- | — | — | — | — | — | — |
| | morpholinopropan-1-one | | | | | | |
| | (Irgacure 307, manufactured by BASF) | | | | | | |
| | 1-(Biphenyl-4-yl)-2-methy1-2- | 1.85 | — | 1.85 | 1.85 | 1.85 | — |
| | morpholinopropan-1-one | | | | | | |
| | (APi 307, manufactured by | | | | | | |
| | Shenzhen UV-ChemTech Ltd.) | | | | | | |
| | Phenylbis(2,4,6-trimethylbenzyl) | — | — | — | — | 0.09 | — |
| | phosphine oxide (Irgacure 819, | | | | | | |
| | manufactured by BASF) | | | | | | |
| | 2,4,6-Trimethylbenzyl- | — | — | — | — | — | 1.85 |
| | diphenylphosphine | | | | | | |
| | oxide (Irgacure TPO, | | | | | | |
| | manufactured by BASF) | | | | | | |
| Blocked isocyanate | Karenz AOI-BM (manufactured by | — | — | — | — | — | — |
| Compound | Showa Denko K. K.) | | | | | | |
| | WT32-B75P (manufactured by | — | — | — | — | 4.46 | 4.46 |
| | Asahi Kasei Corporation) | | | | | | |
| | X6010-4 (manufactured by | 4 46 | 4 46 | 4.46 | 4.46 | — | — |
| | Asahi Kasei Corporation) | | | | | | |
| | The following compound B | 0.74 | 0.74 | 0.74 | 0.74 | 0.74 | 0.74 |
| | The following compound C | — | — | — | — | — | — |
| Additive | N-Phenylglycine (manufactured by | 0.03 | 0.03 | 0.03 | 0.03 | 0.03 | 0.03 |
| | Tokyo Chemical Industry Co., Ltd.) | | | | | | |
| | 1,2,4-Triazole (manufactured by | — | — | — | — | — | — |
| | Otsuka Chemical Co., Ltd.) | | | | | | |
| | Benzimidazole (manufactured by | 0.03 | 0.03 | 0.03 | 0.03 | 0.03 | 0.03 |
| | Tokyo Chemical Industry Co., Ltd.) | | | | | | |
| | 5-Amino-1H-tetrazole (manufactured by | — | — | — | — | — | — |
| | Tokyo Chemical Industry Co., Ltd.) | | | | | | |
| | Isomicotinamide (manufactured by | 0.01 | 0.01 | 0.01 | 0.01 | 0.01 | 0.01 |
| | Tokyo Chemical Industry Co., Ltd.) | | | | | | |
| | SMA EF-40 (manufactured by | 0.30 | 0.30 | 0.30 | 0.30 | 0.30 | 0.30 |
| | Tomoegawa Co., Ltd.) | | | | | | |
| | MEGAFACE F551A (manufactured by | 0.16 | — | — | — | 0.16 | 0.16 |
| | DIC Corporation) | | | | | | |
| | DOWSIL (registered trademark) | — | — | — | — | — | — |
| | 8032 Additive (manufactured by Dow | | | | | | |
| | Corning Toray Co., Ltd.) | | | | | | |
| | Ftergent 710F (manufactured by | — | 0.16 | — | — | — | — |
| | Neos Corporation) | | | | | | |
| | MEGAFACE R-41 (manufactured by | — | — | 0.16 | — | — | — |
| | DIC Corporation) | | | | | | |
| | MEGAFACE F-563 (manufactured by | — | — | — | 0.16 | — | — |
| | DIC Corporation) | | | | | | |
| Solvent | 1-Methoxy-2-propyl acetate | 7.60 | 4.45 | 7.71 | 7.71 | 7.71 | 7.71 |
| | Methyl ethyl ketone | 42.60 | 42.60 | 42.60 | 42.60 | 42.60 | 42.60 |

| | | | | | | |
|---|---|---|---|---|---|---|
| Total (parts by mass) | 100 | 100 | 100 | 100 | 100 | 100 |

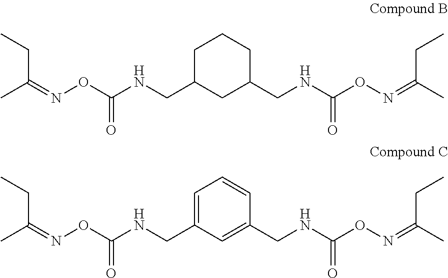

(Preparation of Solution with Solid Content of 36.3% by Mass of Alkali-Soluble Resin P-1)

A solution with a solid content of 36.3% by mass of a polymer P-1 having the following structure (solvent: propylene glycol monomethyl ether acetate) was used. In P-1, the numerical value at the lower right of each constitutional unit indicates a content ratio (% by mole) of each constitutional unit.

A solution of P-1 with a solid content of 36.3% by mass was prepared by a polymerizing step and an additional step shown below.

Polymerizing Step

Propylene glycol monomethyl ether acetate (manufactured by Sanwa Chemical Industrial Co., Ltd., product name PGM-Ac) (60 g) and propylene glycol monomethyl ether (manufactured by Sanwa Chemical Industrial Co., Ltd., product name PGM) (240 g) were introduced into a 2,000 mL flask. The obtained liquid was heated to 90° C. while stirring the liquid at a stirring speed of 250 rpm (round per minute; the same applies hereinafter).

For the preparation of a dropping liquid (1), 107.1 g of methacrylic acid (manufactured by Mitsubishi Rayon Co., Ltd., product name Acryester M), methyl methacrylate (manufactured by Mitsubishi Gas Chemical Company, Inc., product name MMA) (5.46 g), and cyclohexyl methacrylate (manufactured by Mitsubishi Gas Chemical Co., Ltd., product name CHMA) (231.42 g) were mixed and diluted with PGM-Ac (60 g) to obtain the dropping liquid (1).

For the preparation of a dropping liquid (2), dimethyl 2,2′-azobis(2-methylpropionate) (manufactured by FUJIFILM Wako Pure Chemical Corporation, product name V-601) (9.637 g) was dissolved in PGM-Ac (136.56 g) to obtain the dropping liquid (2).

The dropping liquid (1) and the dropping liquid (2) were simultaneously added dropwise to the above-mentioned 2,000 mL flask (specifically, the 2,000 mL flask containing the liquid heated to 90° C.) over 3 hours.

Next, the container of the dropping liquid (1) was washed with PGM-Ac (12 g) and the washing liquid was added dropwise into the 2,000 mL flask. Next, the container of the dropping liquid (2) was washed with PGM-Ac (6 g) and the washing liquid was added dropwise into the 2,000 mL flask. During these dropwise additions, the reaction liquid in the 2,000 mL flask was kept at 90° C. and stirred at a stirring speed of 250 rpm. Further, the mixture was stirred at 90° C. for 1 hour as a post-reaction.

V-601 (2.401 g) was added to the reaction liquid after the post-reaction as the first additional addition of the initiator. Further, the container of V-601 was washed with PGM-Ac (6 g), and the washing liquid was introduced into the reaction liquid. Then, the mixture was stirred at 90° C. for 1 hour.

Next, V-601 (2.401 g) was added to the reaction liquid as the second additional addition of the initiator. Further, the container of V-601 was washed with PGM-Ac (6 g), and the washing liquid was introduced into the reaction liquid. Then, the mixture was stirred at 90° C. for 1 hour.

Next, V-601 (2.401 g) was added to the reaction liquid as the third additional addition of the initiator. Further, the container of V-601 was washed with PGM-Ac (6 g), and the washing liquid was introduced into the reaction liquid. Then, the mixture was stirred at 90° C. for 3 hours.

Additional Step

After stirring at 90° C. for 3 hours, PGM-Ac (178.66 g) was introduced into the reaction liquid. Next, tetraethylammonium bromide (manufactured by FUJIFILM Wako Pure Chemical Corporation) (1.8 g) and hydroquinone monomethyl ether (manufactured by FUJIFILM Wako Pure Chemical Corporation) (0.8 g) were added to the reaction liquid. Further, each container was washed with PGM-Ac (6 g), and the washing liquid was introduced into the reaction liquid. Then, the temperature of the reaction liquid was raised to 100° C.

Next, glycidyl methacrylate (manufactured by NOF Corporation, product name Blemmer G) (76.03 g) was added dropwise to the reaction liquid over 1 hour. The container of Blemmer G was washed with PGM-Ac (6 g), and the washing liquid was introduced into the reaction liquid. Then, the mixture was stirred at 100° C. for 6 hours as an additional reaction.

Next, the reaction liquid was cooled and filtered through a mesh filter (100 meshes) for removing dust to obtain a solution (1,158 g) of the polymer D (concentration of solid contents: 36.3% by mass). The obtained polymer P-1 had a weight-average molecular weight of 27,000, a number-average molecular weight of 15,000, and an acid value of 95 mgKOH/g. P-1 (hereinafter, the molar ratio of the repeating units in the formula was 51.5:2:26.5:20 in the order from the repeating unit on the left side.)

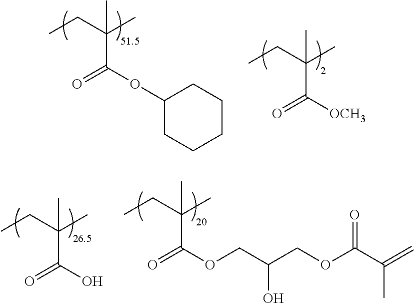

A solution with a solid content of 36.3% by mass (solvent: propylene glycol monomethyl ether acetate) of P-2 was prepared by changing the type and the amount of the monomer of the dropping liquid (1) in the synthesis of P-1. The obtained polymer P-2 had a weight-average molecular weight of 17,000, a number-average molecular weight of 6,200, and an acid value of 95 mgKOH/g.

P-2 (hereinafter, the molar ratio of the repeating units in the formula was 41:15.2:23.9:19.9 in the order from the repeating units on the left side.)

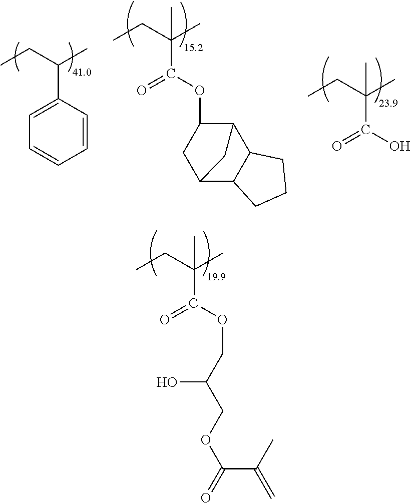

(Preparation of Solution with Solid Content of 36.2% by Mass of Alkali-Soluble Resin P-5)

113.5 g of propylene glycol monomethyl ether was charged into a flask and heated to 90° C. under a nitrogen stream. To this liquid were simultaneously added dropwise a solution in which 172 g of styrene, 4.7 g of methyl methacrylate, and 112.1 g of methacrylic acid had been dissolved in 30 g of propylene glycol monomethyl ether and a solution in which 27.6 g of a polymerization initiator V-601 (manufactured by FUJIFILM Wako Pure Chemical Corporation) had been dissolved in 57.7 g of propylene glycol monomethyl ether over 3 hours. After the dropwise addition, 2.5 g of V-601 was added three times every hour. Thereafter, the reaction was continued for another 3 hours. Thereafter, the reaction liquid was diluted with 160.7 g of propylene glycol monomethyl ether acetate and 233.3 g of propylene glycol monomethyl ether. The reaction liquid was heated to 100° C. under an air stream, and 1.8 g of tetraethylammonium bromide and 0.86 g of p-methoxyphenol were added thereto. 71.9 g of glycidyl methacrylate (Blemmer G manufactured by NOF Corporation) was added dropwise thereto over 20 minutes. The mixture was reacted at 100° C. for 7 hours to obtain a solution of the resin P-5. The concentration of solid contents of the obtained solution was 36.2%. The weight-average molecular weight in terms of standard polystyrene in GPC was 18,000, the dispersity was 2.3, and the acid value of the polymer was 124 mgKOH/g. The amount of residual monomer measured by gas chromatography was less than 0.1% by mass with respect to the solid content of the polymer in any of the monomers.

P-5 (hereinafter, the molar ratio of the repeating units in the formula was 55.1:26.5:1.6:16.9 in the order from the repeating unit on the left side).

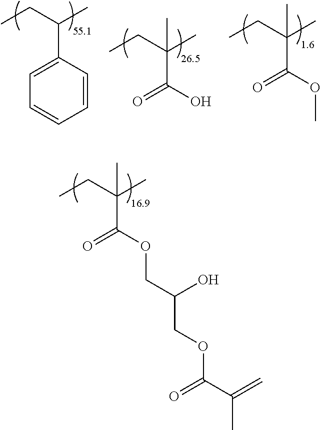

A solution with a solid content of 36.2% by mass solution (solvent: propylene glycol monomethyl ether acetate) of P-6 was prepared by changing the type and the amount of the monomer in the synthesis of P-5. The obtained polymer P-6 had a weight-average molecular weight of 18,000, a dispersity of 2.3, and an acid value of 114 mgKOH/g.

P-6 (hereinafter, the molar ratio of the repeating units in the formula was 55.1:24.6:1.6:17.0:1.7 in the order from the repeating unit on the left side.)

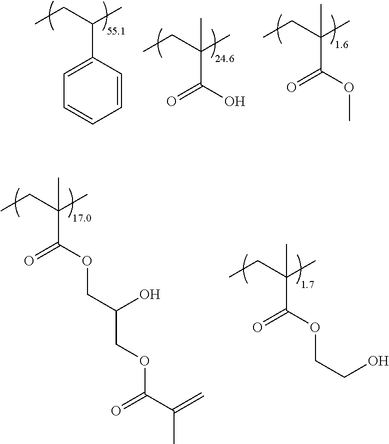

<Preparation of Composition for Forming Refractive Index-Adjusting Layer>

Next, compositions B to B-4 for forming a refractive index-adjusting layer were prepared with the compositions shown in Table 8 below. The numerical values in Table 6 represent “parts by mass”.

TABLE 8

| Raw material | | B | B-2 | B-3 | B-4 |
|---|---|---|---|---|---|
| NanoUse OZS-30M: | | 4.88 | 4.34 | 4.34 | 4.34 |
| ZrO₂ particles (containing tin oxide) methanol | | | | | |
| dispersion liquid (manufactured by Nissan Chemical | | | | | |
| Industries. Ltd.) | | | | | |
| Ammonia water (25%) | | 7.84 | 7.84 | 7.84 | 7.84 |
| Binder | Polymer A (methacrylic acid/allyl | 0.07 | 0.21 | 0.21 | 0.21 |
| polymer | methacrylate copolymer resin) | | | | |
| | ARUFON UC-3920 | 0.02 | 0.01 | 0.01 | 0.01 |
| | (manufactured by (manufactured | | | | |
| | by Toagosei Co., Ltd.)) | | | | |

| | | | | |
|---|---|---|---|---|
| Monomer with carboxyl group | 0.03 | 0.03 | 0.03 | 0.03 |
| ARONIX TO-2349 ((manufactured by Toagosei Co., | | | | |
| Ltd.)) | | | | |
| 1,2,4-Triazole (manufactured by Otsuka Chemical | 0.03 | | 0.03 | |
| Co., Ltd.) | | | | |
| N-Methyldiethanolamine (Nippon Nyukazai Co., | | 0.03 | 0.03 | 0.03 |
| Ltd.) | | | | |
| Adenine (KJ Chemicals Corporation) | | 0.03 | | 0.03 |
| MEGAPACE F444 (manufactured by DIC | 0.01 | 0.01 | | |
| Corporation) | | | | |
| Ftergent 215M (manufactured by Neos Corporation) | | | 0.01 | 0.01 |
| Ion exchange water | 20.9 | 21.3 | 21.3 | 21.3 |
| Methanol | 66.2 | 66.2 | 66.2 | 66.2 |
| Total (parts by mass) | 100 | 100 | 100 | 100 |

The polymer Ain Table 8 was synthesized as follows.

I-Methoxypropanol (manufactured by Tokyo Chemical Industry Co., Ltd.) (270.0 g) was introduced into a 1 L three-neck flask, and a temperature thereof was raised to 70° C. under a nitrogen stream under stirring. Meanwhile, allyl methacrylate (45.6 g) (manufactured by Fujifilm Wako Pure Chemical Industries, Ltd.) and methacrylic acid (14.4 g) (manufactured by Fujifilm Wako Pure Chemical Industries, Ltd.) were dissolved in 1-methoxypropanol (manufactured by Tokyo Chemical Industry Co., Ltd.) (270.0 g), 3.94 g of V-65 (manufactured by Fujifilm Wako Pure Chemical Industries, Ltd.) was further dissolved therein to produce a dropping liquid, and the liquid was added dropwise to a flask over 2.5 hours. The reaction was performed while keeping the stirred state as it was for 2.0 hours.

Then, the temperature was returned to room temperature, and the mixture was added dropwise to ion exchange water (2.7 L) in a stirred state and subjected to reprecipitation to obtain a turbid solution. The filtration was carried out by introducing a turbid solution in Nutche with a filter paper, and the filtered material was further washed with ion exchange water to obtain a wet powder. The powder was dried by blowing air at 45° C. to confirm that the amount was constant, thereby obtaining a polymer A as a powder in a yield of 70%.

The ratio of methacrylic acid/allyl methacrylate of the obtained polymer A was 76/24% by mass. The weight-average molecular weight thereof was 38,000.

### Example 1

A photosensitive composition A-1 was applied to a temporary support of a polyethylene terephthalate film (Lumirror 16KS40 (manufactured by Toray Industries, Inc.)) having a thickness of 16 μm, using a slit-shaped nozzle, while the coating amount of the photosensitive composition A-1 was adjusted so that the thickness of the photosensitive composition layer after drying was 8 μm. Next, for the obtained temporary support, the solvent was volatilized in a drying zone at 100° C. to form a photosensitive composition layer. Then, a protective film (Lumirror 16KS40 (manufactured by Toray Industries, Inc.)) was pressure-bonded to the photosensitive composition layer to manufacture a transfer film X1 shown in Table 8.

### Examples 2 to 32 and Comparative Examples 1 to 4

Transfer films X2-32 and C1-4 were obtained according to the same procedure as in Example 1, except that the photosensitive compositions A-2 to A-32 and A′-1 to A′-4 were used instead of the photosensitive composition A-1.

### Examples 33 to 52

Transfer films X33 to X52 were obtained according to the same procedure as in Example 1, except that the photosensitive compositions A-33 to A-52 were used instead of the photosensitive composition A-1 and the coating amount was adjusted so that the thickness of the photosensitive composition layer after drying was 5.0 μm.

<Production of Laminate>

A cycloolefin resin film having a film thickness of 38 μm and a refractive index of 1.53 was subjected to a corona discharge treatment for 3 seconds under the conditions of an electrode length of 240 mm, and a distance between work electrodes of 1.5 mm at an output voltage of 100% and an output of 250 W with a wire electrode having a diameter of 1.2 mm by using a high frequency oscillator, to carry out the surface reforming, thereby obtaining a transparent substrate.

Next, a material-C shown in Table 9 was coated on a corona discharge-treated surface of the transparent substrate using a slit-shaped nozzle, then irradiated with ultraviolet rays (integrated light amount of 300 mJ/cm²), and dried at approximately 110° C. to form a transparent film having a refractive index of 1.60 and a film thickness of 80 nm.

TABLE 9

| Raw material | |
|---|---|
| ZrO₂: ZR-010 manufactured by Solar Corporation | 2.08 |
| DPHA liquid (Dipival erythritol hexaacrylate: 38%, Dipival erythritol pentaacrylate: 38%, 1-methoxy-2-propyl acetate: | 0.29 |
| 24%) | |
| Urethane-based monomer: UK Oligo UA-32P manufactured by Shin-Nakamura Chemical Co., Ltd: 75% non-volatile | 0.14 |
| content, 1-methoxy-2-propyl acetate: 25% | |
| Monomer mixture (polymerizable compound (b2-1) described in paragraph [0111] of JP2012-078528A), n = 1: Trine- | 0.36 |
| pentaerythritol octaacrylate content 85%, a sum of n = 2 and n = 3 as an impurity is 15%) | |
| Polymer solution 1 (Structural Formula P-25 described in paragraph [0058] of JP 2008-146018A: weight-average | 1.89 |
| molecular weight = 35,000, solid content 45%, 1-methoxy-2-propyl acetate 15%, 1-methoxy-2-propanol 40%) | |
| Photoradical polymerization initiator: 2-benzyl-2-dimethylamine-1-(4 morpholinophenyl butanone) (Igracure (registered | 0.03 |
| trademark) 379, manufactured by BASF) | |
| Photopolymerization initiator: Kayacure DETX-S (Nippon Kayaku Co., Ltd., alkyl thioxanthone) | 0.03 |
| Polymer solution 2 (polymer with the structural formula shown in the following table (3): solution with a weight-average | 0.01 |
| molecular weight of 15,000, non-volatile content 30% by mass, methyl ethyl ketone 70% by mass) | |
| 1-Methoxy-2-propyl acetate | 38.73 |
| Methyl ethyl ketone | 56.80 |
| Total (parts by mass) | 100 |

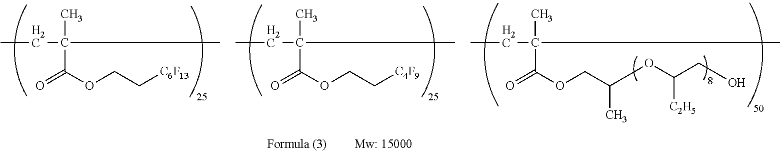

Next, a film in which the transparent film was formed on a transparent substrate was introduced into a vacuum chamber, and an ITO thin film having a thickness of 40 nm and a refractive index of 1.82 was formed on the transparent film, using an ITO target (indium:tin=95:5 (molar ratio)) having a SnO₂ content of 10% by mass, by a direct current (DC) magnetron sputtering (conditions: temperature of transparent substrate: 150° C., argon pressure: 0.13 Pa, oxygen pressure: 0.01 Pa). A surface electrical resistance of the ITO thin film was 80Ω/□(square per Q).

Next, the ITO thin film was etched and patterned by a known chemical etching method to obtain a conductive substrate having a transparent film and a transparent electrode part on the transparent substrate.

The protective film of the transfer film 1 obtained above was peeled, the surface of the exposed photosensitive composition layer was brought into contact with the forming surface of the transparent electrode part of the conductive substrate and laminated so that the photosensitive composition layer covered (was pressure-bonded to) the transparent electrode part to form a laminate in which the photosensitive composition layer and the temporary support were arranged on the conductive substrate.

Furthermore, the lamination was performed under the conditions in which a temperature of transparent substrate was 40° C., a rubber roller temperature was 100° C., a linear pressure was 3 N/cm, and a transportation speed was 2 m/min, by using a vacuum laminator manufactured by MCK Co., Ltd.

Thereafter, using a proximity type exposure machine (manufactured by Hitachi High-Tech Electronics Engineering Co., Ltd.) including an ultra-high pressure mercury lamp, a surface of an exposure mask (quartz exposure mask including a pattern for forming an overcoat) and the temporary support were closely attached, and the laminate was exposed in a patterned shape with an exposure amount of 60 mJ/cm² (i-line) through the temporary support.

Furthermore, a main wavelength of the exposure light at the time of irradiation was from light at a wavelength of 365 nm.

Then, after the temporary support was peeled from the laminate, the exposed photosensitive composition layer was developed for 60 seconds using a 1% by mass aqueous sodium carbonate solution at a temperature of 32° C. Thereafter, the residue was removed by spraying ultrapure water from an ultra-high pressure washing nozzle onto the laminate after the development treatment. Subsequently, air was blown onto a surface of the laminated cheer to remove the moisture.

Next, the obtained pattern was exposed with an exposure amount of 400 mJ/cm² (i-line) using a post-exposure machine (manufactured by Ushio, Inc.) including a high pressure mercury lamp (post-exposure).

Then, the pattern was subjected to a post-baking treatment at 145° C. for 30 minutes to form a laminate LX1 having the transparent film, the transparent electrode part, and the pattern (a cured film of a photosensitive composition layer) in this order on the transparent substrate.

Laminates LX2 to 52 and LC1 to LC1 to 4 were formed according to the procedure, except that the transfer films X2 to 52 and C1 to C4 were used instead of the transfer films X1.

<Evaluation of Edge Shape (Pattern Linearity)>

An evaluation sample was manufactured according to the same procedure as <Method for Producing Laminate> above, except that the exposing treatment was performed using an exposure mask having a line/space of 50 μm/50 μm as the exposure mask.

An edge portion of the pattern in the manufactured evaluation sample was visually observed and observed with an optical microscope (objective 20 times). The shape of an edge portion (the linearity of a pattern) was evaluated according to the following evaluation standard.

<<Evaluation Standards>>

A: An edge of a pattern is clean even in a case of being observed with an optical microscope.

B: Some unevenness is observed on an edge of a pattern in a case of being observed with an optical microscope.

C: Unevenness is clearly observed on an edge of a pattern in a case of being observed with an optical microscope although not being found visible.

D: Concavities and convexities are clearly observed on an edge of a pattern visually.

<Evaluation of Scratch Resistance (Evaluation of Surface Scratch)>

During the procedure of <Method for Manufacturing Laminate> above, an evaluation sample which had been subjected to post-exposure was manufactured. Then, a surface of the pattern was rubbed with gauze, and the surface of the pattern was visually observed and observed with a microscope (objective 5 times).

<<Evaluation Standards>>

A: No scratches can be seen on the entire surface of a pattern through both visual observation and observing with an optical microscope.

B: No scratches can be seen through visual observation and scratches can be seen through observation with an optical microscope.

C: Slight scratches can be seen in some spots through visual observation.

D: Obvious scratches can be seen through visual observation.

In Tables 10 to 12, the symbols in the “Type” column in the “First photopolymerization initiator” column and the “Type” column in the “Second photopolymerization initiator” column each represent the following ones.

“OXE02”:
1-[9-Ethyl-6-(2-methylbenzoyl)-9H-carbazole-3-yl]ethanone-1-(0-acetyloxime) (OXE-02, manufactured by BASF)

“OXE01”: 1-[4-(Phenylthio)phenyl]octane-1,2-dione-2-(O-benzoyloxime) (OXE01, manufactured by BASF)

“OXE03”:
[8-[5-(2,4,6-Trimethylphenyl)-11-(2-ethylhexyl)-11H-benzo[a]carbazoyl]][2-(2,2,3,3-tetrafluo ropropoxy)phenyl]methanone-(O-acetyloxime) (OXE-03, manufactured by BASF) “Irgacure 379EG”:
2-(Dimethylamino)-2-(4-methylbenzyl)-1-(4-morpholinophenyl)butane-1-one (Irgacure 379EG, manufactured by BASF)

“DAROCUR EDB”: Ethyl 4-(dimethylamino)benzoate (DAROCUR EDB, manufactured by BASF)

“Irgacure 2959”: 2-Hydroxy-4′-(2-hydroxyethoxy)-2-methylpropiophenone (Irgacure 2959, manufactured by BASF)

“Irgacure 307”: 1-(Biphenyl-4-yl)-2-methyl-2-morpholinopropan-1-one (Irgacure 307, manufactured by BASF)

“Irgacure 819”: Phenylbis(2,4,6-trimethylbenzoyl)phosphine oxide

“Irgacure TPO”: 2,4,6-Trimethylbenzoyludiphenylphosphine oxide

In Tables 10 to 12, “ε1” represents a molar absorption coefficient of the first photopolymerization initiator at a wavelength of 365 nm, “ε2” represents a molar absorption coefficient of the second photopolymerization initiator at a wavelength of 365 nm, and “ε3” represents a molar absorption coefficient of the second photopolymerization initiator at a wavelength of 313 nm.

TABLE 10

| | | | First photopolymerization initiator | | | |
|---|---|---|---|---|---|---|
| | | | | | Maximum | |
| | Photosensitive | Transfer | | ε1 | absorption | Second photopolymerization initiator |
| | composition | film | Type | [L/(mol · cm)]] | wavelength | Type |
| Example 1 | A-1 | X1 | OXE02 | 2,723 | 338 nm | DAROCUR |
| | | | | | | EDB |
| Example 2 | A-2 | X2 | OXE02 | 2,723 | 338 nm | Irgacure 2959 |
| Example 3 | A-3 | X3 | OXE02 | 2,723 | 338 nm | Irgacure 307 |
| Example 4 | A-4 | X4 | OXE02 | 2,723 | 338 nm | Irgacure 379EG |
| Example 5 | A-5 | X5 | OXE02 | 2,723 | 338 nm | Irgacure 819 |
| Example 6 | A-6 | X6 | OXE01 | 2,367 | 326 nm | DAROCUR |
| | | | | | | EDB |
| Example 7 | A-7 | X7 | OXE03 | 14,895 | 358 nm | DAROCUR |
| | | | | | | EDB |
| Example 8 | A-8 | X8 | Irgacure | 1,229 | 320 nm | DAROCUR |
| | | | 379EG | | | EDB |
| Example 9 | A-9 | X9 | OXE02 | 2,723 | 338 nm | DAROCUR |
| | | | | | | EDB |
| Example 10 | A-10 | X10 | OXE02 | 2,723 | 338 nm | DAROCUR |
| | | | | | | EDB |
| Example 11 | A-11 | X11 | OXE02 | 2,723 | 338 nm | DAROCUR |
| | | | | | | EDB |
| Example 12 | A-12 | X12 | OXE02 | 2,723 | 338 nm | DAROCUR |
| | | | | | | EDB |
| Example 13 | A-13 | X13 | OXE02 | 2,723 | 338 nm | DAROCUR |
| | | | | | | EDB |
| Example 14 | A-14 | X14 | OXE02 | 2,723 | 338 nm | DAROCUR |
| | | | | | | EDB |
| Example 15 | A-15 | X15 | OXE02 | 2,723 | 338 nm | DAROCUR |
| | | | | | | EDB |
| Example 16 | A-16 | X16 | OXE02 | 2,723 | 338 nm | DAROCUR |
| | | | | | | EDB |
| Comparative | A′-1 | C1 | OXE02 | 2,723 | 338 nm | — |
| Example 1 | | | | | | |
| Comparative | A′-2 | C2 | OXE02 | 2,723 | 338 nm | — |
| Example 2 | | | | | | |
| Comparative | A′-3 | C3 | OXE02 | 2,723 | 338 nm | OXE01 |
| Example 3 | | | | | | |
| Comparative | A′-4 | C4 | Irgacure | 435 | 301 nm | Api 307 |
| Example 4 | | | TPO | | | |

| | Second photopolymerization initiator | | | | | | |
|---|---|---|---|---|---|---|---|
| | | | | Maximum | | Evaluation | |
| | ε2 | ε3 | | absorption | | Edge | Scratch |
| | [L/(mol · cm)]] | [L/(mol · cm)]] | ε2/ε3 | wavelength | ε2/ε1 | shape | resistance |
| Example 1 | 19 | 19,000 | 0.001 | 308 nm | 0.01 | A | A |
| Example 2 | 0 | — | 0 | 273 nm | 0.00 | A | A |
| Example 3 | 150 | 4,688 | 0.032 | 281 nm | 0.06 | A | A |
| Example 4 | 1,229 | 153,625 | 0.008 | 320 nm | 0.45 | A | A |
| Example 5 | 863 | 6,077 | 0.142 | 290 nm | 0.32 | A | A |
| Example 6 | 19 | 19,000 | 0.001 | 308 nm | 0.01 | A | A |
| Example 7 | 19 | 19,000 | 0.001 | 308 nm | 0.00 | A | A |
| Example 8 | 19 | 19,000 | 0.001 | 308 nm | 0.02 | A | A |
| Example 9 | 19 | 19,000 | 0.001 | 308 nm | 0.01 | A | A |
| Example 10 | 19 | 19,000 | 0.001 | 308 nm | 0.01 | A | A |
| Example 11 | 19 | 19,000 | 0.001 | 308 nm | 0.01 | A | A |
| Example 12 | 19 | 19,000 | 0.001 | 308 nm | 0.01 | A | A |
| Example 13 | 19 | 19,000 | 0.001 | 308 nm | 0.01 | A | A |
| Example 14 | 19 | 19,000 | 0.001 | 308 nm | 0.01 | A | A |
| Example 15 | 19 | 19,000 | 0.001 | 308 nm | 0.01 | A | A |
| Example 16 | 19 | 19,000 | 0.001 | 308 nm | 0.01 | A | A |
| Comparative | — | — | — | — | — | A | D |
| Example 1 | | | | | | | |
| Comparative | — | — | — | — | — | D | A |
| Example 2 | | | | | | | |
| Comparative | 2,367 | 10,203 | 0.232 | 326 nm | 0.87 | A | D |
| Example 3 | | | | | | | |
| Comparative | 150 | 4,688 | 0.032 | 281 nm | 0.34 | D | A |
| Example 4 | | | | | | | |

TABLE 11

| | | | First photopolymerization initiator | | | |
|---|---|---|---|---|---|---|
| | | | | | Maximum | |
| | Photosensitive | Transfer | | ε1 | absorption | Second photopolymerization initiator |
| | composition | film | Type | [L/mol · cm)]] | wavelength | Type |
| Example 17 | A-17 | X17 | OXE02 | 2,723 | 338 nm | DAROCUR |
| | | | | | | EDB |
| Example 18 | A-18 | X18 | OXE02 | 2,723 | 338 nm | Irgacure 2959 |
| Example 19 | A-19 | X19 | OXE02 | 2,723 | 338 nm | Irgacure 307 |
| Example 2G | A-20 | X20 | OXE02 | 2,723 | 338 nm | Irgacure 379EG |
| Example 21 | A-21 | X21 | OXE02 | 2,723 | 338 nm | Irgacure 819 |
| Example 22 | A-22 | X22 | OXE01 | 2,367 | 326 nm | DAROCUR |
| | | | | | | EDB |
| Example 23 | A-23 | X23 | OXE03 | 14,895 | 358 nm | DAROCUR |
| | | | | | | EDB |
| Example 24 | A-24 | X24 | Irgacure | 1,229 | 320 nm | DAROCUR |
| | | | 379EG | | | EDB |
| Example 25 | A-25 | X25 | OXE02 | 2,723 | 338 nm | DAROCUR |
| | | | | | | EDB |
| Example 26 | A-26 | X26 | OXE02 | 2,723 | 338 nm | DAROCUR |
| | | | | | | EDB |
| Example 27 | A-27 | X27 | OXE02 | 2,723 | 338 nm | DAROCUR |
| | | | | | | EDB |
| Example 28 | A-28 | X28 | OXE02 | 2,723 | 338 nm | DAROCUR |
| | | | | | | EDB |
| Example 29 | A-29 | X29 | OXE02 | 2,723 | 338 nm | DAROCUR |
| | | | | | | EDB |
| Example 30 | A-30 | X30 | OXE02 | 2,723 | 338 nm | DAROCUR |
| | | | | | | EDB |
| Example 31 | A-31 | X31 | OXE02 | 2,723 | 338 nm | DAROCUR |
| | | | | | | EDB |
| Example 32 | A-32 | X32 | OXE02 | 2,723 | 338 nm | DAROCUR |
| | | | | | | EDB |

| | Second photopolymerization initiator | | | | | | |
|---|---|---|---|---|---|---|---|
| | | | | Maximum | | Evaluation | |
| | ε2 | ε3 | | absorption | | Edge | Scratch |
| | [L/mol · cm)]] | [L/mol · cm)]] | ε2/ε3 | wavelength | ε2/ε1 | shape | resistance |
| Example 17 | 19 | 19,000 | 0 | 308 nm | 0.01 | A | A |
| Example 18 | 0 | — | 0 | 273 nm | 0.00 | A | A |
| Example 19 | 150 | 4,688 | 0.03 | 281 nm | 0.06 | A | A |
| Example 2G | 1,229 | 153,625 | 0.01 | 320 nm | 0.45 | A | A |
| Example 21 | 863 | 6,077 | 0.14 | 290 nm | 0.32 | A | A |
| Example 22 | 19 | 19,000 | 0 | 308 nm | 0.01 | A | A |
| Example 23 | 19 | 19,000 | 0 | 308 nm | 0.00 | A | A |
| Example 24 | 19 | 19,000 | 0 | 308 nm | 0.02 | A | A |
| Example 25 | 19 | 19,000 | 0 | 308 nm | 0.01 | A | A |
| Example 26 | 19 | 19,000 | 0 | 308 nm | 0.01 | A | A |
| Example 27 | 19 | 19,000 | 0 | 308 nm | 0.01 | A | A |
| Example 28 | 19 | 19,000 | 0 | 308 nm | 0.01 | A | A |
| Example 29 | 19 | 19,000 | 0 | 308 nm | 0.01 | A | A |
| Example 30 | 19 | 19,000 | 0 | 308 nm | 0.01 | A | A |
| Example 31 | 19 | 19,000 | 0 | 308 nm | 0.01 | A | A |
| Example 32 | 19 | 19,000 | 0 | 308 nm | 0.01 | A | A |

TABLE 12

| | | | First photopolymerization initiator | | | |
|---|---|---|---|---|---|---|
| | | | | | Maximum | |
| | Photosensitive | Transfer | | ε1 | absorption | Second photopolymerization initiator |
| | composition | film | Type | [L/(mol · cm)]] | wavelength | Type |
| Example 33 | A-33 | X-33 | OXE02 | 2,723 | 338 nm | Api 307 |
| Example 34 | A-34 | X-34 | OXE02 | 2,723 | 338 nm | Api 307 |
| Example 35 | A-35 | X-35 | OXE02 | 2,723 | 338 nm | Api 307 |
| Example 36 | A-36 | X-36 | OXE02 | 2,723 | 338 nm | Api 307 |
| Example 37 | A-37 | X-37 | OXE02 | 2,723 | 338 nm | Api 307 |
| Example 38 | A-38 | X-38 | OXE02 | 2,723 | 338 nm | Api 307 |
| Example 39 | A-39 | X-39 | OXE02 | 2,723 | 338 nm | Api 307 |
| Example 40 | A-40 | X-40 | OXE02 | 2,723 | 338 nm | Api 307 |
| Example 41 | A-41 | X-41 | OXE02 | 2,723 | 338 nm | Api 307 |
| Example 42 | A-42 | X-42 | OXE02 | 2,723 | 338 nm | Api 307 |
| Example 43 | A-43 | X-43 | OXE02 | 2,723 | 338 nm | Api 307 |
| Example 44 | A-44 | X-44 | OXE02 | 2,723 | 338 nm | Api 307 |
| Example 45 | A-45 | X-45 | OXE02 | 2,723 | 338 nm | Api 307 |
| Example 46 | A-46 | X-46 | OXE02 | 2,723 | 338 nm | Irgacure 2959 |
| Example 47 | A-47 | X-47 | Irgacure | 1,229 | 320 nm | Api 307 |
| | | | 379EG | | | |
| Example 48 | A-48 | X-48 | Irgacure | 1,229 | 320 nm | Irgacure 2959 |
| | | | 379EG | | | |
| Example 49 | A-49 | X-49 | OXE02 | 2,723 | 338 nm | Api 307 |
| Example 50 | A-50 | X-50 | OXE02 | 2,723 | 338 nm | Api 307 |
| Example 51 | A-51 | X-51 | Irgacure | 863 | 287 nm | Api 307 |
| | | | 819 | | | |
| Example 52 | A-52 | X-52 | OXE02 | 2,723 | 338 nm | Irgacure TPO |

| | Second photopolymerization initiator | | | | | | |
|---|---|---|---|---|---|---|---|
| | | | | Maximum | | Evaluation | |
| | ε2 | ε3 | | absorption | | Edge | Scratch |
| | [L/(mol · cm)]] | [L/(mol · cm)]] | ε2/ε3 | wavelength | ε2/ε1 | shape | resistance |
| Example 33 | 150 | 4,688 | 0.032 | 281 nm | 0.06 | A | A |
| Example 34 | 150 | 4,688 | 0.032 | 281 nm | 0.06 | A | A |
| Example 35 | 150 | 4,688 | 0.032 | 281 nm | 0.06 | A | A |
| Example 36 | 150 | 4,688 | 0.032 | 281 nm | 0.06 | A | A |
| Example 37 | 150 | 4,688 | 0.032 | 281 nm | 0.06 | A | A |
| Example 38 | 150 | 4,688 | 0.032 | 281 nm | 0.06 | A | A |
| Example 39 | 150 | 4,688 | 0.032 | 281 nm | 0.06 | A | A |
| Example 40 | 150 | 4,688 | 0.032 | 281 nm | 0.06 | A | A |
| Example 41 | 150 | 4,688 | 0.032 | 281 nm | 0.06 | A | A |
| Example 42 | 150 | 4,688 | 0.032 | 281 nm | 0.06 | A | A |
| Example 43 | 150 | 4,688 | 0.032 | 281 nm | 0.06 | A | A |
| Example 44 | 150 | 4,688 | 0.032 | 281 nm | 0.06 | A | A |
| Example 45 | 150 | 4,688 | 0.032 | 281 nm | 0.06 | A | A |
| Example 46 | 0 | — | 0 | 273 nm | 0.00 | A | A |
| Example 47 | 150 | 4,688 | 0.032 | 281 nm | 0.12 | A | A |
| Example 48 | 0 | — | 0 | 273 nm | 0.00 | A | A |
| Example 49 | 150 | 4,688 | 0.032 | 281 nm | 0.06 | A | A |
| Example 50 | 150 | 4,688 | 0.032 | 281 nm | 0.06 | A | A |
| Example 51 | 150 | 4,688 | 0.032 | 281 nm | 0.17 | B | A |
| Example 52 | 435 | 2,214 | 0.196 | 301 nm | 0.16 | A | B |

As shown in Tables 10 to 12, it was confirmed that a desired effect can be obtained by using the transfer film according to the embodiment of the present invention.

### Examples 101 to 152

A composition B for forming the refractive index-adjusting layer was applied to the photosensitive composition layer, using a slit-shaped nozzle, while the coating amount of the composition B for forming the refractive index-adjusting layer was adjusted so that the thickness of the refractive index-adjusting layer after drying was 70 μm in the manufacture of a transfer film of Example 1. Next, the obtained coating film was dried at a drying temperature of 80° C. to form a refractive index-adjusting layer on the photosensitive composition layer.

Furthermore, a refractive index of the refractive index-adjusting layer was 1.68.

Next, a protective film (Lumirror 16KS40 (manufactured by Toray Industries, Inc.)) was pressure-bonded to a surface of the refractive index-adjusting layer to manufacture a transfer film Y1.

Transfer films Y2 to Y52 including the refractive index-adjusting layer, corresponding to Examples 101 to 152, were manufactured by carrying out the same procedure as above even in the manufacture of transfer films of Examples 2 to 52.

The same evaluations as in <Evaluation of Edge Shape (Pattern Linearity)> and <Evaluation of Scratch Resistance (Evaluation of Surface Scratch)> were performed using each of these transfer films Y1 to Y52, and thus, the same results as the results of the transfer films of Examples 1 to 52 corresponding to the aspects including no refractive index-adjusting layer of each transfer film could be obtained. That is, for example, the same evaluation results were obtained with the transfer film X1 and the transfer film Y1 further having a refractive index-adjusting layer on the transfer film X1 of Example 1.

In addition, the transfer films Y34-2 to Y34-4 were manufactured by carrying out the same procedure as above, except that the composition B for forming a refractive index-adjusting layer was changed to B-2 to B4 in the manufacture of the transfer film of Y34. The same evaluations as in <Evaluation of Edge Shape (Pattern Linearity)> and <Evaluation of Scratch Resistance (Evaluation of Surface Scratch)> were performed using each of these transfer films Y34-2 to Y34-4, and thus, the same results as the results of the transfer films of Example 34 corresponding to the aspects including no refractive index-adjusting layer of each transfer film could be obtained.

Transfer films having photosensitive resin layers with different thicknesses were manufactured in the same manner as in Example 1, except that the coating amount in Example 1 was adjust to set the thickness of the photosensitive resin layer to 1.0 μm, 2.0 μm, and 4.0 μm, respectively, and the transfer films were subjected to the same evaluations as in <Evaluation of Edge Shape (Pattern Linearity)> and <Evaluation of Scratch Resistance (Evaluation of Surface Scratch)>, and thus, the same evaluation results as in Example 1 could be obtained with any of the transfer films.

Transfer films having photosensitive resin layers with different thicknesses were manufactured in the same manner as in Example 1, except that the coating amount in Example 34 was adjusted to set the thickness of the photosensitive resin layer to 1.0 μm, 2.0 μm, 4.0 μm, and 8.0 μm respectively, and the transfer films were subjected to the same evaluations as in <Evaluation of Edge Shape (Pattern Linearity)> and <Evaluation of Scratch Resistance (Evaluation of Surface Scratch)>, and thus, the same evaluation results as in Example 34 could be obtained with any of the transfer films.

Transfer films having refractive index-adjusting layers with different thicknesses were manufactured in the same manner as in Y34, except that the thickness of the refractive index-adjusting layer was adjusted to 40 nm, 100 nm, and 150 nm, respectively, in the transfer film Y34, the transfer films were subjected to the same evaluations as in <Evaluation of Edge Shape (Pattern Linearity)> and <Evaluation of Scratch Resistance (Evaluation of Surface Scratch)>, and thus, the same evaluation results as with Y34 could be obtained with any of the transfer films.

What is claimed is:

1. A transfer film comprising:
a temporary support; and
a photosensitive composition layer,
wherein the photosensitive composition layer includes a photopolymerization initiator, an alkali-soluble resin, and a polymerizable compound,
the photopolymerization initiator includes a first photopolymerization initiator and a second photopolymerization initiator,
a molar absorption coefficient ε1 of the first photopolymerization initiator at a wavelength of 365 nm is 500 L/mol·cm or more, and
a ratio of a molar absorption coefficient ε2 of the second photopolymerization initiator at a wavelength of 365 nm to a molar absorption coefficient ε3 of the second photopolymerization initiator at a wavelength of 313 nm is 0.200 or less.

2. The transfer film according to claim 1,
wherein the ratio of the molar absorption coefficient ε2 of the second photopolymerization initiator at a wavelength of 365 nm to the molar absorption coefficient ε3 of the second photopolymerization initiator at a wavelength of 313 nm is 0.100 or less.

3. The transfer film according to claim 1,
wherein a maximum absorption wavelength of the second photopolymerization initiator is 320 nm or less.

4. The transfer film according to claim 1,
wherein a maximum absorption wavelength of the second photopolymerization initiator is 300 nm or less.

5. The transfer film according to claim 1,
wherein the second photopolymerization initiator includes at least one selected from the group consisting of an aminobenzoate-based photopolymerization initiator, an alkylphenone-based photopolymerization initiator, and an acylphosphine oxide-based photopolymerization initiator.

6. The transfer film according to claim 1,
wherein the second photopolymerization initiator includes an aminobenzoate-based photopolymerization initiator.

7. The transfer film according to claim 1,
wherein the first photopolymerization initiator includes at least one selected from the group consisting of an oxime ester-based photopolymerization initiator and an alkylphenone-based photopolymerization initiator.

8. The transfer film according to claim 1,
wherein a ratio of the molar absorption coefficient ε2 of the second photopolymerization initiator at a wavelength of 365 nm to the molar absorption coefficient ε1 of the first photopolymerization initiator at a wavelength of 365 nm is 0.50 or less.

9. The transfer film according to claim 1,
wherein the photosensitive composition layer is used for forming an electrode protective film.

10. The transfer film according to claim 1, further comprising a refractive index-adjusting layer,
wherein the refractive index-adjusting layer is arranged in contact with the photosensitive composition layer, and
a refractive index of the refractive index-adjusting layer is 1.60 or more.

11. The transfer film according to claim 1,
wherein the second photopolymerization initiator includes an aminobenzoate-based photopolymerization initiator, and
a maximum absorption wavelength of the second photopolymerization initiator is 300 nm or less.

12. A method for producing a laminate, comprising:
affixing the transfer film according to claim 1 to a substrate having a conductive layer, with a photosensitive composition layer side of the transfer film thus facing the substrate, to obtain a substrate with a photosensitive composition layer;
exposing of pattern-exposing the photosensitive composition layer with light having a wavelength of 365 nm as a main wavelength;
developing the exposed photosensitive composition layer to form a pattern;
post-exposing of irradiating the pattern with light with which the second photopolymerization initiator is photosensitized; and
further, peeling the temporary support from the substrate with a photosensitive composition layer, between the affixing and the exposing, or between the exposing and the developing.

13. The method for producing a laminate according to claim 12,
wherein the substrate having a conductive layer is a substrate having a sensor electrode part for a touch panel and a lead wire part conducting with the sensor electrode for a touch panel.
